(19) United States
(12) Patent Application Publication
(10) Pub. No.: US 2011/0310537 A1
(43) Pub. Date: Dec. 22, 2011

(54) ELECTRONIC DEVICE AND COMPUTER PROGRAM PRODUCT

(75) Inventors: Akira IMAMURA, Hamura-shi (JP); Shinsuke YATO, Akishima-shi (JP)

(73) Assignee: KABUSHIKI KAISHA TOSHIBA, Tokyo (JP)

(21) Appl. No.: 13/046,506

(22) Filed: Mar. 11, 2011

(30) Foreign Application Priority Data
Jun. 18, 2010 (JP) 2010-139767

(51) Int. Cl. H05K 7/00

(52) U.S. Cl. 361/679.01

(57) ABSTRACT

According to one embodiment, an electronic device includes a display module, at least one function button, an operation-mode identifying module, and a function switching module. The display module displays thereon display data processed by an application running on an operating system (OS) or display data based on received broadcast waves. The function button is provided separately from a hardware keyboard on which a plurality of keys are arranged. The operation-mode identifying module identifies a mode of operation with respect to the function button. The function switching module controls switching a plurality of functions defined by the OS or an application running on the OS depending on the mode of operation identified by the operation-mode identifying module.

### CROSS-REFERENCE TO RELATED APPLICATIONS

This application is based upon and claims the benefit of priority from Japanese Patent Application No. 2010-139767, filed Jun. 18, 2010, the entire contents of which are incorporated herein by reference.

### FIELD

Embodiments described herein relate generally to an electronic device and a computer program product.

### BACKGROUND

There are conventionally known electronic devices equipped with operation buttons, such as a power button, on the same screen as a display. In recent years, there are known devices with a PC system installed in a case shaped like a television set, and some devices have a Windows (registered trademark) system.

In a typical PC system, at the time of operating a power switch, a function called SAS (Secure Attention Sequence) for maintaining an application of the system and the like can be executed by pressing “CTRL”, “ALT”, and “DEL” keys provided on a keyboard at the same time. For example, when an application makes no response, a menu is opened by pressing the “CTRL”, “ALT”, and “DEL” keys at the same time, and the non-responding application can be forced to quit.

In recent years, there has been developed an electronic device equipped with no hardware keyboard; the electronic device displays a software keyboard, which is activated by running an application on an OS, on a display so that the software keyboard is used together with a touch panel attached to the display.

Such an electronic device or the like is not equipped with a hardware keyboard, so if an application for a software keyboard makes no response, it is not possible to press the “CTRL”, “ALT”, and “DEL” keys, and therefore it is not possible to execute the SAS as described above.

Incidentally, to resolve such a problem, it is conceivable to pre-install a key for executing the SAS; however, from the aspect of requirements on design, installation of many keys or buttons leads to a decrease in design of the device. Especially, demands to reduce the number of keys or buttons are prominent in small devices.

### BRIEF DESCRIPTION OF THE SEVERAL VIEWS OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary front view illustrating an example of an electronic device according to a first embodiment;

FIG. 2 is an exemplary cross-section view of the electronic device along a line II-II in FIG. 1 in the first embodiment;

FIG. 3 is an exemplary side view illustrating an elastic bushing incorporated in the electronic device illustrated in FIG. 1 in the first embodiment;

FIG. 4 is an exemplary cross-section view of the electronic device along a line IV-IV in FIG. 1 in the first embodiment;

FIG. 5 is an exemplary cross-section view of the electronic device along a line V-V in FIG. 1 in the first embodiment;

FIG. 6 is an exemplary front view illustrating a display screen of the electronic device illustrated in FIG. 1 in the first embodiment;

FIG. 7 is an exemplary appearance diagram illustrating an operation button provided on the user's left-hand side of the electronic device illustrated in FIG. 1 in the first embodiment;

FIG. 8 is an exemplary appearance diagram illustrating an operation button provided on the user's right-hand side of the electronic device illustrated in FIG. 1 in the first embodiment;

FIG. 9 is an exemplary block diagram illustrating a control system of the electronic device illustrated in FIG. 1 in the first embodiment;

FIG. 10 is an exemplary functional block diagram illustrating functions implemented by a system BIOS in the first embodiment;

FIG. 11 is an exemplary flowchart of a process performed by the system BIOS in the first embodiment;

FIG. 12 is an exemplary front view of an “OS boot menu” in the first embodiment;

FIG. 13 is an exemplary front view of a “HW diagnostic mode/BIOS initialize menu” in the first embodiment;

FIG. 14 is an exemplary front view of a display of a “boot select mode” in the first embodiment;

FIG. 15 is an exemplary functional block diagram illustrating functions implemented by an OS or an application program in the first embodiment;

FIG. 16 is an exemplary flowchart of a process performed by the OS or application program in the first embodiment;

FIG. 17 is an exemplary flowchart of a process performed by the OS or application program in the first embodiment;

FIG. 18 is an exemplary perspective view of an electronic device according to a second embodiment;

FIG. 19 is an exemplary appearance perspective view illustrating a closed state of the electronic device illustrated in FIG. 18 in the second embodiment;

FIG. 20 is an exemplary exploded perspective view of the electronic device illustrated in FIG. 18 in the second embodiment;

FIG. 21 is an exemplary perspective view illustrating the side of a back surface of a first main body portion of the electronic device illustrated in FIG. 18, and is an exemplary diagram illustrating a state in which a battery pack placed on the side of the back surface is removed in the second embodiment;

FIG. 22 is an exemplary perspective view illustrating the side of aback surface of a touch panel unit of the first main body portion of the electronic device illustrated in FIG. 18, and is an exemplary diagram illustrating a state in which an operation-mechanism supporting member is removed in the second embodiment;

FIG. 23 is an exemplary perspective view illustrating a state in which the operation-mechanism supporting member is attached to the structure illustrated in FIG. 22 in the second embodiment;

FIG. 24 is an exemplary cross-section view of the electronic device along a line XV-XV in FIG. 18 in the second embodiment;

FIG. 25 is an exemplary cross-section view of the electronic device along a line XVI-XVI in FIG. 18 in the second embodiment;

FIG. 26 is an exemplary perspective view of the operation-mechanism supporting member of the electronic device illustrated in FIG. 18 viewed from the front side in the second embodiment;

FIG. 27 is an exemplary perspective view illustrating a cover body of an operation mechanism of the electronic device illustrated in FIG. 18 in the second embodiment;

FIG. 28A is an exemplary plan view of the cover body illustrated in FIG. 27 viewed from the front in the second embodiment;

FIG. 28B is an exemplary side view of the cover body illustrated in FIG. 27 viewed from the side in the second embodiment;

FIG. 28C is an exemplary bottom view of the cover body illustrated in FIG. 27 viewed from the bottom in the second embodiment;

FIG. 29 is an exemplary appearance diagram illustrating an operation button provided on the left-hand side of the first main body portion of the electronic device illustrated in FIG. 18 in the second embodiment;

FIG. 30 is an exemplary appearance diagram illustrating an operation button provided on the right-hand side of the first main body portion of the electronic device illustrated in FIG. 18 in the second embodiment;

FIG. 31 is an exemplary appearance perspective view illustrating an example in which one image is displayed on over two displays of the electronic device illustrated in FIG. 18 in the second embodiment;

FIG. 32 is an exemplary appearance perspective view illustrating an example in which a keyboard is displayed on the display of the first main body portion illustrated in FIG. 31 in the second embodiment;

FIG. 33 is an exemplary appearance perspective view illustrating an example in which a mousepad is displayed on the display of the first main body portion illustrated in FIG. 31 in the second embodiment;

FIG. 34 is an exemplary block diagram illustrating a control system of the electronic device illustrated in FIG. 18 in the second embodiment;

FIG. 35 is an exemplary functional block diagram illustrating functions implemented by an OS or an application program in the second embodiment;

FIG. 36 is an exemplary flowchart of a process performed by the OS or application program in the second embodiment;

FIG. 37 is an exemplary front view of a menu for implementing an SAS function in the second embodiment;

FIG. 38 is an exemplary flowchart of a process performed by the OS or application program in the second embodiment;

FIG. 39 is an exemplary front view of a launcher in the second embodiment;

FIG. 40 is an exemplary cross-section view of the electronic device along a line XXVII-XXVII in FIG. 18 in the second embodiment;

FIG. 41 is an exemplary functional block diagram illustrating functions implemented by a system BIOS in the second embodiment;

FIG. 42 is an exemplary flowchart of a process performed by the system BIOS in the second embodiment;

FIG. 43 is an exemplary front view of an “OS boot menu” in the second embodiment;

FIG. 44 is an exemplary front view of a “HW diagnostic mode/BIOS initialize menu” in the second embodiment;

FIG. 45 is an exemplary front view of a display of a “boot select mode” in the second embodiment;

FIG. 46 is an exemplary front view of icons representing functions of the buttons in the second embodiment; and

FIG. 47 is an exemplary front view illustrating an example in which the number of operation buttons is increased according to a modification of the second embodiment.

### DETAILED DESCRIPTION

In general, according to one embodiment, an electronic device comprises a display module, at least one function button, an operation-mode identifying module, and a function switching module. The display module is configured to display thereon display data processed in accordance with an application running on an operating system (OS) or display data on the basis of received broadcast waves. The function button is provided separately from a hardware keyboard on which a plurality of keys are arranged. The operation-mode identifying module is configured to identify various modes of operation with respect to the function button. The function switching module is configured to control switching a plurality of functions defined by the OS or an application running on the OS depending on the mode of operation identified by the operation-mode identifying module.

According to another embodiment, an electronic device comprises a display module, at least one function button, an operation-mode identifying module, and a function switching module. The display module is configured to display thereon a keyboard on which a plurality of keys are arranged in accordance with an application running on an operating system (OS). The function button is provided separately from a hardware keyboard on which a plurality of keys are arranged. The operation-mode identifying module is configured to identify various modes of operation with respect to the function button. The function switching module is configured to control switching a plurality of functions defined by the OS or an application running on the OS depending on the mode of operation identified by the operation-mode identifying module.

According to still another embodiment, a computer program product has a computer readable medium including programmed instructions. The instructions, when executed by a computer, cause the computer to implement an operation-mode identifying module configured to identify various modes of operation with respect to at least one function button provided separately from a hardware keyboard on which a plurality of keys are arranged and a function switching module configured to control switching a plurality of functions defined by an operating system (OS) or an application running on the OS depending on the mode of operation identified by the operation-mode identifying module.

### First Embodiment

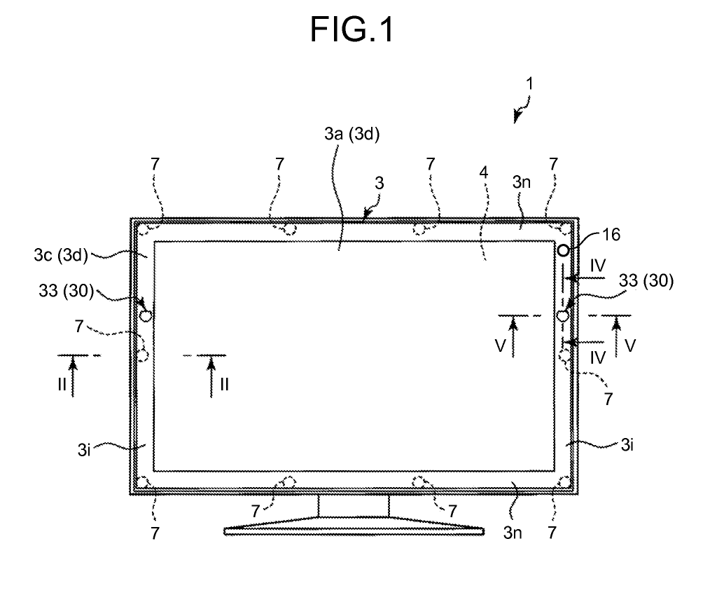

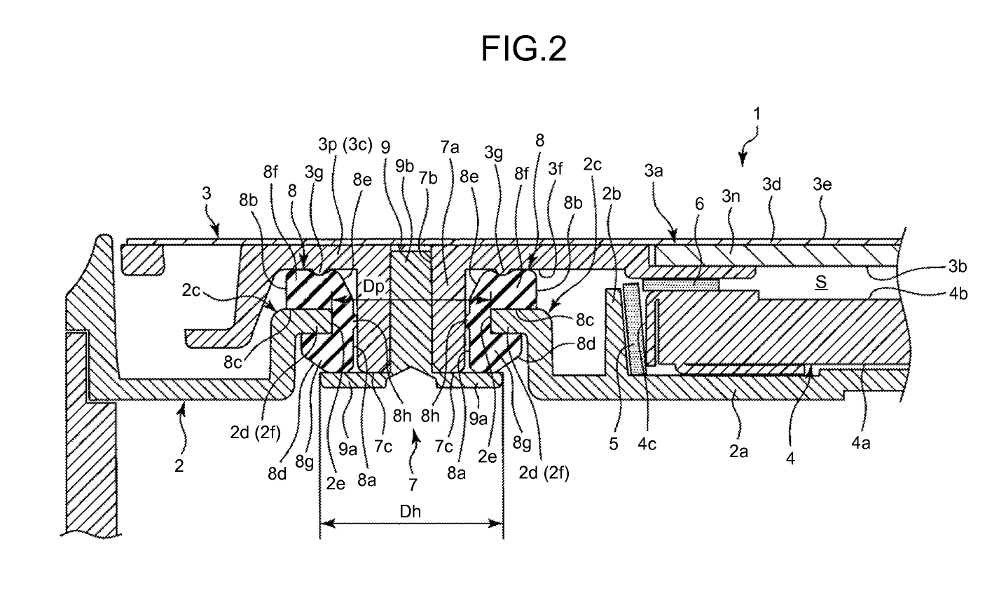

FIG. 1 is a front view illustrating an example of an all-in-one personal computer (hereinafter, referred to as “AIO”) 1 as an electronic device according to a first embodiment. The AIO 1 has a rectangular appearance when viewed from the front, i.e., from an anterior view (a planar view with respect to the front surface). The AIO 1 is a personal computer that comes with major peripherals and contains a main body of the personal computer, a keyboard, and a mouse, as well as a display, a sound card, a speaker, a modem (or a network card), and the like in advance, and is preinstalled with an OS such as Windows (registered trademark). The AIO 1 comprises an enclosure 2 (see FIG. 2) and a touch panel 3a which is swingably supported by the enclosure 2. Furthermore, as illustrated in FIG. 2, on the side of a back surface 3b of the touch panel 3a (the lower side in FIG. 2), a display 4, such as a liquid crystal display (LCD), is placed as a display module (a display). The display 4 is fixed to the enclosure 2 placed on the side of a back surface 4a of the display 4 with a screw (not illustrated) or the like.

As illustrated in FIGS. 1 and 2, on the periphery of the touch panel 3a formed into a thin rectangular sheet, a frame 3c formed into a rectangular frame is placed. The frame 3c is formed of a synthetic resin material, a metallic material, or the like. The touch panel 3a and the frame 3c are attached to a transparent cover 3d formed of, for example, a thin sheet, film, or plate-like synthetic resin material or the like with a double-stick tape (not illustrated), an adhesive, or the like. The touch panel 3a and the frame 3c are integrated via the cover 3d. Furthermore, a peripheral portion 3n of the touch panel 3a is held between the frame 3c and the cover 3d. Incidentally, the periphery of the cover 3d is colored in, for example, black so as to prevent the peripheral portion 3n of the touch panel 3a and the frame 3c from coming out to the side of a front surface 3e of a touch panel unit 3 (the upper side in FIG. 2). In the present embodiment, the touch panel unit 3 as a panel unit is composed of the touch panel 3a, the frame 3c, and the cover 3d.

As illustrated in FIG. 2, the enclosure 2 has a rectangular plate-like bottom wall portion 2a on which the display 4 is put and a longitudinal wall portion 2b which projects forward (upward in FIG. 2) from the bottom wall portion 2a and faces a side surface 4c of the display 4. In the present embodiment, a plurality of longitudinal wall portions 2b are partially placed at intervals along the periphery (the side surface 4c) of the display 4. The longitudinal wall portions 2b can work as a positioning module when the display 4 is installed to the enclosure 2 and also an energy absorbing module, for example, when an impact load in a lateral direction (a right-left direction in FIG. 2) acts on the display 4. Furthermore, an elastic member 5, such as a sponge or elastomer, lies between the side surface 4c of the display 4 and each of the longitudinal wall portions 2b. By the use of the elastic member 5, backlash of the display 4 is suppressed, and the energy absorption performance is further enhanced.

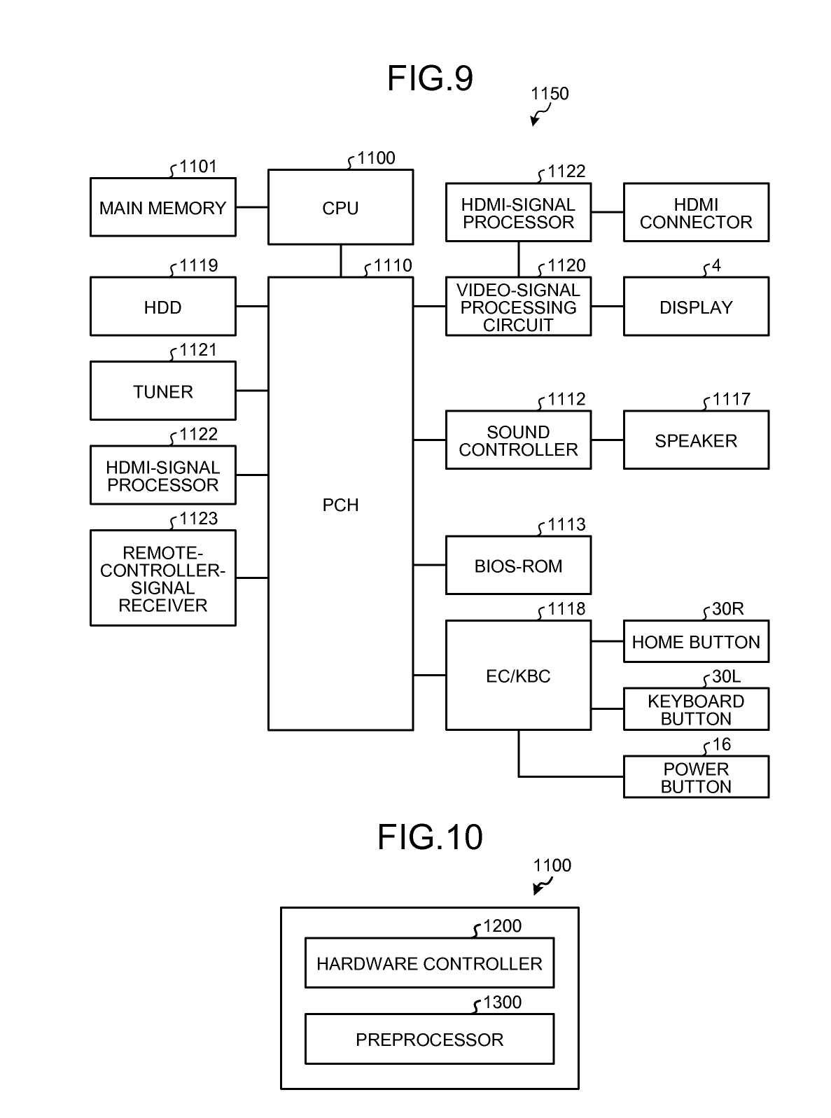

The display 4 is formed into a flattened rectangular solid. The display 4 receives a video signal from a video-signal processing circuit 1120 (see FIG. 9) contained in a control circuit 1150 (see FIG. 9) which is composed of electronic parts and the like and mounted on a circuit board, and displays thereon an image, such as a still image or a moving image. A light representing the image displayed on a front surface 4b as a display screen of the display 4 passes through the clear transparent touch panel 3a and is projected forward.

The touch panel 3a has two transparent conductive films pasted together (not illustrated); when a user touches the touch panel 3a with his/her finger, a stylus, or the like, the transparent conductive films conduct electricity at the position of a touched portion of the touch panel 3a, so the touched position can be detected. A signal indicating the touched position of the touch panel 3a is sent to the control module described above, and the control module executes a process based on the signal. Incidentally, the touch panel 3a is not limited to such a resistive (pressure-sensitive) type touch panel; alternatively, the touch panel 3a can be a capacitive type touch panel or other types of touch panels.

The AIO 1 of the present embodiment comprises a vibrating mechanism (not illustrated here). The vibrating mechanism has, for example, a motor and an eccentric weight which is rotated by the motor, and is installed to the side of a back surface 3f of a rectangular frame-like and plate-like front wall portion 3p of the frame 3c. The control module of the AIO 1 activates the vibrating mechanism when the touch panel 3a is touched, and, for example, the vibrating mechanism vibrates the touch panel unit 3. Therefore, an operator (a user) can recognize that the pressing operation with respect to the touch panel 3a is accepted by the vibration felt via the finger or stylus, etc. touching the touch panel 3a.

A belt-like seal member 6 is placed between the front surface 4b of the display 4 and the back surface 3f of the frame 3c along the periphery of the front surface 4b of the display 4. The seal member 6 is formed of a flexible member, such as a sponge, and prevents the entry of a foreign substance or the like from the outside into a space S between the front surface 4b of the display 4 and the back surface 3b of the touch panel 3a. Incidentally, a force of bounce generated by the seal member 6 is set to small so as not to affect swing or vibration of the touch panel unit 3. Namely, the seal member 6 does not practically contribute to the support of the touch panel unit 3 by the enclosure 2.

As illustrated in FIGS. 1 and 2, the touch panel unit 3 as a front panel is swingably supported by the enclosure 2 as a supporting base via a plurality of swing supporting mechanisms (connecting mechanisms) 7. The touch panel unit 3 can swing in a front-back direction (a direction perpendicular to the front surface 3e, an up-down direction in FIG. 2) and the lateral direction (a direction along the front surface 3e, the right-left direction in FIG. 2, a direction perpendicular to the plane of the drawing, etc.) relative to the enclosure 2. The plurality of swing supporting mechanisms 7 are arranged along the periphery of the touch panel unit 3; preferably, the swing supporting mechanisms 7 are symmetrically placed with respect to at least either one of two center lines parallel to four sides of a rectangle of the touch panel 3a viewed from the front, and four or more swing supporting mechanisms 7 are placed. The swing supporting mechanisms 7 support the frame 3c of the touch panel unit 3.

In the present embodiment, as illustrated in FIG. 2, the swing supporting mechanism 7 has a support bracket portion 2c provided to the enclosure 2, an elastic bushing 8 attached to the support bracket portion 2c, a connecting portion 7a penetrating through a through-hole 8a formed as a penetration portion on the elastic bushing 8, and a screw 9 as a uniting body attached to the connecting portion 7a. In the present embodiment, the support bracket portion 2c corresponds to a base portion. Furthermore, the frame 3c corresponds to a frame member, and the front wall portion 3p of the frame 3c corresponds to a supported portion.

The support bracket portion 2c is provided to the periphery of the bottom wall portion 2a of the enclosure 2 as a boss portion cylindrically projecting forward, i.e., toward the side of the front wall portion 3p provided as a supported portion. Furthermore, a circular through-hole 2e is formed on the center of a top wall portion 2d of the support bracket portion 2c, and an inward flange portion 2f is formed around the through-hole 2e.

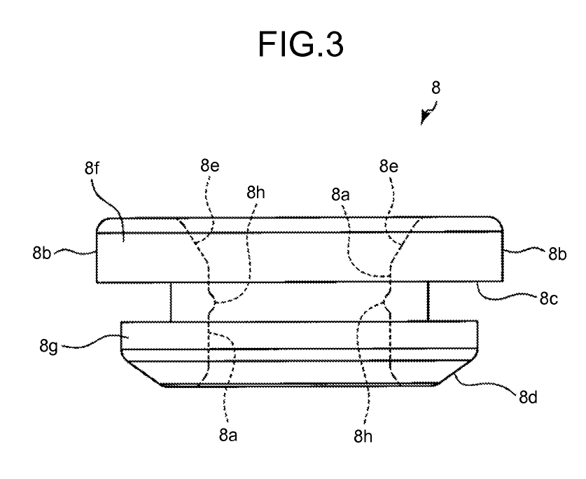

The elastic bushing 8 is formed of an elastic material having the flexibility higher than the enclosure 2 and the frame 3c (the connecting portion 7a), such as elastomer (for example, synthetic rubber), into a cylindrical shape. As illustrated in FIGS. 2 and 3, on the center of an outer circumferential surface 8b of the elastic bushing 8 in an axial direction (the up-down direction in FIGS. 2 and 3), an outer circumferential groove 8c is formed over the whole circumference in a circumferential direction. By fitting the outer circumferential groove 8c with the flange portion 2f of the support bracket portion 2c, the elastic bushing 8 is attached to the support bracket portion 2c.

As the elastic bushing 8 deforms elastically, a worker inserts the elastic bushing 8 into the through-hole 2e from the front side so that the elastic bushing 8 can be relatively easily attached to the support bracket portion 2c. The elastic bushing 8 here has an asymmetric shape, i.e., the elastic bushing 8 is asymmetrical on the both sides in the axial direction. This prevents the worker from attaching the elastic bushing 8 in a wrong posture to the support bracket portion 2c. Furthermore, as illustrated in FIGS. 2 and 3, an outwardly-narrowed inclined surface 8d is formed at the periphery of an end of the elastic bushing 8 on the side of a head portion 9a of the screw 9. The inclined surface 8d works as a guide when the elastic bushing 8 is inserted into the through-hole 2e. Moreover, as illustrated in FIGS. 2 and 3, an outwardly-widened inclined surface 8e is formed at the periphery of an end of the through-hole 8a on the side of the support bracket portion 2c. The inclined surface 8e works as a guide when the connecting portion 7a is inserted into the through-hole 8a. Furthermore, the inclined surface 8e works to prevent the posture of the attached elastic bushing 8 from being worsened by preventing the elastic bushing 8 from being squeezed when the connecting portion 7a is inserted into the through-hole 8a.

The connecting portion 7a is formed as a boss portion cylindrically projecting backward from the frame 3c. As illustrated in FIG. 2, in an assembled state, the connecting portion 7a penetrates through the through-hole 2e of the support bracket portion 2c, and projects to the side of the back surface (the rear surface) of the support bracket portion 2c. On the connecting portion 7a, a female screw hole 7b opening backward is formed as a female screw portion. Incidentally, in the present embodiment, the female screw hole 7b is formed as a through-hole penetrating through the front wall portion 3p of the frame 3c; alternatively, the female screw hole 7b can be formed as a bottomed hole with an opening to the back side only.

The screw 9 has the head portion 9a and a male screw portion 9b screwed into the female screw hole 7b. The screw 9 is screwed until the head portion 9a butts an end surface 7c of the connecting portion 7a.

A worker attaches the elastic bushing 8 to the support bracket portion 2c from the front side, and brings the touch panel unit 3 close to the enclosure 2 from the front and inserts the connecting portion 7a into the through-hole 8a of the elastic bushing 8, and then tightens up the screw 9 into the female screw hole 7b of the connecting portion 7a provide as a boss portion from the back side, thereby the swing supporting mechanism 7 illustrated in FIG. 2 is composed. Namely, it is configured that the elastic bushing 8 is fitted into the support bracket portion 2c, so the worker can perform the assembly work more easily and smoothly as compared with the case of adhering or screwing an elastic body.

In the present embodiment, the connecting portion 7a penetrates through the through-hole 8a of the elastic bushing 8 in the front-back direction of the display 4. Consequently, a worker just overlays the touch panel unit 3 on the display 4, so that it comes into a state where the connecting portion 7a is inserted into the through-hole 8a, and therefore the assembly work can be performed more easily and smoothly.

In the present embodiment, as illustrated in FIG. 2, in a state where the swing supporting mechanisms 7 have been assembled, a front-side protrudent portion 8f of the elastic bushing 8 lies between the support bracket portion 2c as a part of the enclosure 2 and the frame 3c of the touch panel unit 3 placed on the front side of the support bracket portion 2c, and a back-side protrudent portion 8g of the elastic bushing 8 lies between the support bracket portion 2c and the screw 9 placed on the back side of the support bracket portion 2c. Namely, as for both a force acting on the touch panel unit 3 in a forward-to-backward direction (an external force, an inertial force, etc.) and a force acting on the touch panel unit 3 in a backward-to-forward direction, it is easier to make a force of bounce of the elastic bushing 8 act equally, and therefore it is easier to suppress variations in swing (vibration) directing to forward of the touch panel unit 3 and swing (vibration) directing to backward of the touch panel unit 3. Furthermore, the elastic bushing 8 is placed so as to surround the connecting portion 7a, so it is possible to suppress a variation in swing characteristics (vibration characteristics) of the touch panel unit 3 in the lateral direction. Incidentally, from the viewpoint of ease of swing (vibration), it is preferable that an initial load (a load in a state where no external force acts except its own weight), which is caused by holding the member, on the front-side protrudent portion 8f and the back-side protrudent portion 8g is set to relatively small.

In the present embodiment, the support bracket portion 2c is formed as a boss portion projecting forward (i.e., toward the side of the front wall portion 3p of the frame 3c) from the bottom wall portion 2a of the enclosure 2. Therefore, the swing supporting mechanisms 7 are prevented from being protruded backward from the bottom wall portion 2a, and it is easier to fit the swing supporting mechanisms 7 inside the enclosure 2. Moreover, the held elastic bushing 8 is in contact with the front wall portion 3p as a base of the frame 3c, so there is no need to provide a contact portion with the elastic bushing 8 comes on the frame 3c in addition to the front wall portion 3p, and therefore the configuration of the swing supporting mechanisms 7 can be further simplified.

Further, in the swing supporting mechanisms 7 configured as described above, as the area of contact between the touch panel unit 3 and the elastic bushing 8 increases, the touch panel unit 3 is made less likely to vibrate. Consequently, in the present embodiment, there is provided a structure for reducing the area of contact between the elastic bushing 8 and the touch panel unit 3 in the assembled state. As an example, a circular projection portion 8h is provided on an inner surface of the through-hole 8a of the elastic bushing 8. By the projection portion 8h, an area of contact between the inner surface of the through-hole 8a and an outer surface of the connecting portion 7a is reduced. Furthermore, as another example, a plurality of projection portions 3g are circumferentially placed on a portion of the back surface 3f of the frame 3c opposed to the elastic bushing 8. By the projection portions 3g, an area of contact between the back surface 3f of the frame 3c and the front surface of the elastic bushing 8 is reduced. Incidentally, these are only examples; alternatively, for example, a projection portion can be provided to the connecting portion 7a or the front surface of the elastic bushing 8, and the projection portion can be formed into a circular shape or a plurality of projection portions can be circumferentially placed.

In the present embodiment, an outer diameter Dh of the head portion 9a is larger than an inner diameter Dp of the through-hole 2e of the support bracket portion 2c. Consequently, even if the elastic bushing 8 cannot be attached to the support bracket portion 2c faultily, or even if the elastic bushing 8 comes off from the support bracket portion 2c due to time degradation or the like, the screw 9 is prevented from coming off from the through-hole 2e of the support bracket portion 2c, and therefore the touch panel unit 3 is prevented from coming off from the enclosure 2. Furthermore, a washer (not illustrated) can be put between the head portion 9a and the elastic bushing 8. By putting the washer between them, the elastic bushing 8 can be prevented from being kinked when the screw 9 is tightened. Incidentally, in that case, an outer diameter of the washer is just set to be larger than the inner diameter Dp of the through-hole 2e.

In the present embodiment, a push button mechanism 30 and a power button 16 operated to power on or power off the AIO 1 are exposed on the front surface of the touch panel unit 3 swingably-supported by the enclosure 2. The push button mechanism 30 has a cover body 33 as a movable portion which can be moved relative to the frame 3c, and receives a push operation from the side of the front surface (front face) of the display 4.

In the present embodiment, as illustrated in FIG. 1, the push button mechanism 30 is provided to each of a pair of right and left-hand vertical frame portions 3i of the frame 3c which extend in the up-down direction like belts. Furthermore, the push button mechanism 30 is placed between a plurality of (in the present embodiment, two) support positions where the frame 3c is supported by the swing supporting mechanisms 7.

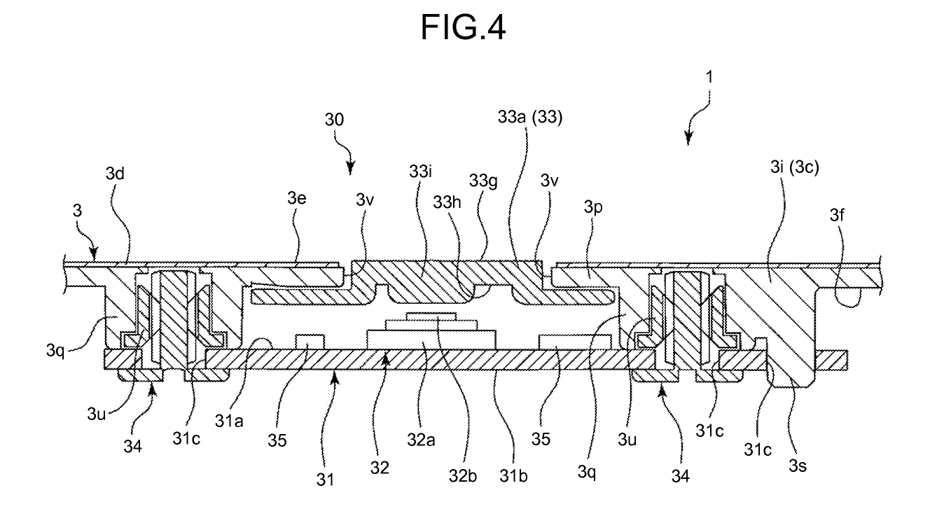

As illustrated in FIGS. 4 and 5, the push button mechanism 30 has a circuit board 31 as an operation mechanism supporting member, a push-button switch 32 mounted on the circuit board 31 as an operation mechanism main body, and a cover body 33 for covering the push-button switch 32.

The circuit board 31 is placed on the back side of the front wall portion 3p of the frame 3c to be spaced from the front wall portion 3p and parallel to the front wall portion 3p. Namely, the circuit board 31 is placed in a posture that a front surface 31a is directed forward and a back surface 31b is directed backward.

As illustrated in FIG. 4, on the front wall portion 3p of the frame 3c, a boss portion 3q projecting backward is provided as a supporting-member fixing module. A plurality of (in the present embodiment, two for each push button mechanism 30) boss portions 3q are provided at intervals along the peripheral portion 3n of the touch panel 3a (see FIG. 5). Each of the boss portions 3q is fitted with a tubular female screw member 3u by insert molding or the like. A screw 34 penetrating through a through-hole 31c of the circuit board 31 is inserted into the female screw member 3u and tightened, thereby the circuit board 31 is fixed to the boss portion 3q. Furthermore, on the front wall portion 3p, a projection portion 3s projecting backward is provided. On the circuit board 31, the through-hole 31c through which the projection portion 3s penetrates is formed. The projection portion 3s and the through-hole 31c through which the projection portion 3s penetrates work as a positioning module for positioning the circuit board 31. Incidentally, the projection portion 3s and the adjacent boss portion 3q are integrated via a rib or the like.

In the present embodiment, the circuit board 31 is configured as a printed circuit board. On the front surface 31a of the circuit board 31 opposed to the back surface 3f of the front wall portion 3p, the push-button switch 32, parts 35, and the like are mounted by soldering or the like. The push-button switch 32 is connected to the control circuit 1150 (see FIG. 9) including a CPU and the like via, although not illustrated in the drawing, a wiring pattern formed on the circuit board 31, a connector as one of the parts 35 mounted on the circuit board 31, a harness connected to the connector, and the like.

The push-button switch 32 has a main body portion 32a and a movable portion 32b which is projectably and sinkably provided to the main body portion 32a. The movable portion 32b can project and sink in the front-back direction with respect to the main body portion 32a. The push-button switch 32 contains a pair of contacts including a fixed contact and a movable contact (both not illustrated), and a circuit containing the pair of contacts is closed by the connection of the pair of contacts.

The cover body 33 covers the front of the push-button switch 32 at a distance. The cover body 33 is formed of an elastic body containing elastomer, synthetic resin, or the like. The cover body 33 is fixed to the back surface 3f of the front wall portion 3p, for example, by welding, adhesive bonding, or the like. On the front wall portion 3p, a through-hole 3v is formed as a penetration portion. An operation portion 33a of the cover body 33 penetrates through the through-hole 3v and is exposed on the side of the front surface 3e of the touch panel unit 3. In the present embodiment, a top surface 33g of the operation portion 33a and the front surface 3e of the touch panel unit 3 are set on about the same level. When the cover body 33 is pressed from the front side thereof with a user's finger or the like, the cover body 33 elastically deforms and bends backward (the lower side in FIGS. 4 and 5), and the operation portion 33a sinks beneath the front surface 3e; when the cover body 33 is released from being pressed, the cover body 33 returns forward and is back in an initial state (installed state).

As illustrated in FIG. 5, on the side of a rear surface 33h of the operation portion 33a, a projection portion 33i opposed to the movable portion 32b and a projection portion 33j opposed to the front surface 31a of the circuit board 31 at the position away from the movable portion 32b are provided. The projection portion 33i thrusts the movable portion 32b when the cover body 33 is pressed. The projection portion 33j has contact with the front surface 31a of the circuit board 31 when the operation portion 33a is pressed with a user's finger or the like at the position away from the push-button switch 32 (for example, a right-hand end portion of the operation portion 33a in FIG. 5), and works as a supporting strut. If the projection portion 33j is not provided, the operation portion 33a is tilted backward with increasing distance between the operation portion 33a and the push-button switch 32, and the operation portion 33a may not be able to press the movable portion 32b straight down. On this regard, in the present embodiment, the projection portion 33j works as a supporting strut, so the projection portion 33j prevents the operation portion 33a from being tilted, and the operation portion 33a can thrust the movable portion 32b more reliably. Namely, in the present embodiment, the projection portion 33j corresponds to a tilt preventing portion. Such a configuration is effective in the case where the operation portion 33a of the cover body 33 is wide relative to the push-button switch 32. Namely, by providing the projection portion 33j, the size of the push-button switch 32 can be reduced and the size of the operation portion 33a can be increased. Incidentally, the tilt restraining module can be provided on the side of the circuit board 31 as a projection portion (for example, a stud or the like).

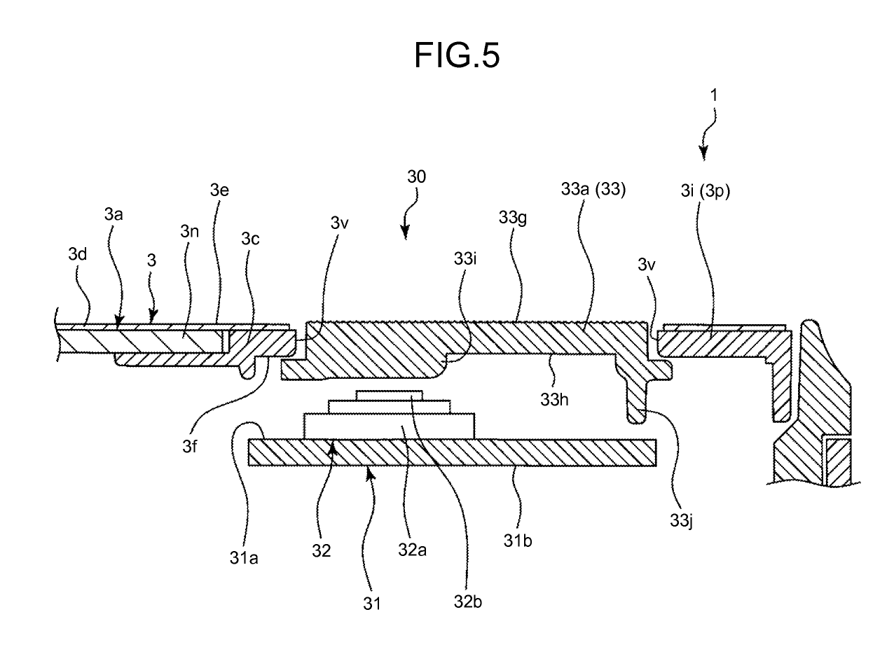

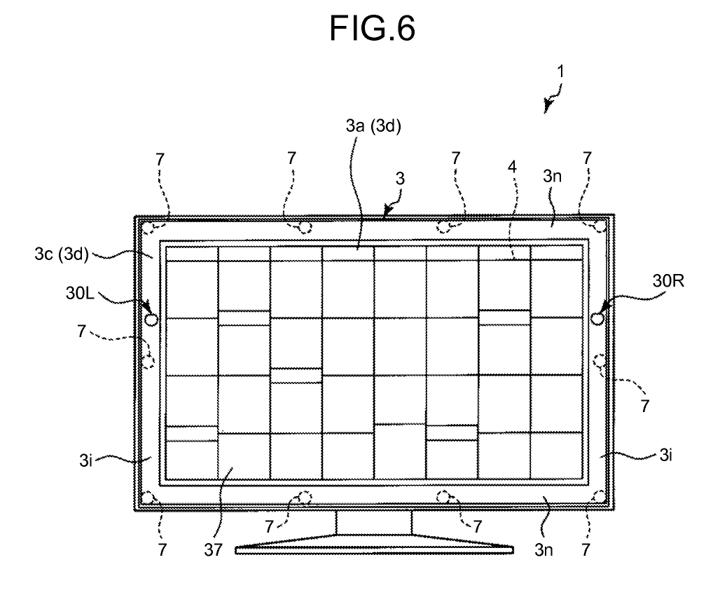

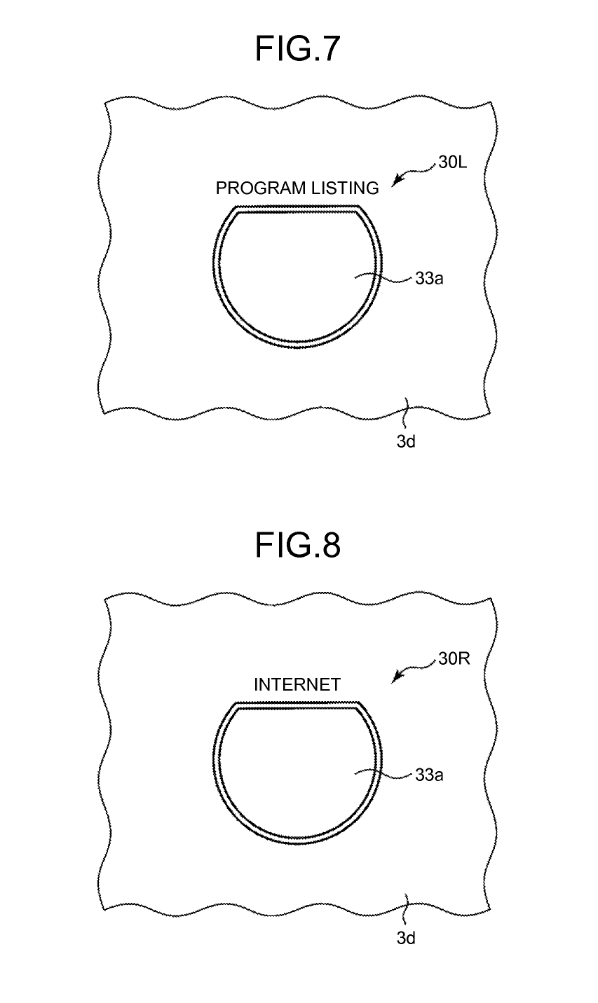

In the present embodiment, the left-hand push button mechanism 30 illustrated in FIG. 1 is assigned to work as an operation button 30L (FIG. 7) for displaying, for example, a screen illustrated in FIG. 6. The screen in FIG. 6 is, for example, a program listing. Furthermore, in the present embodiment, the right-hand push button mechanism 30 in FIG. 1 is assigned to work as an operation button 30R (FIG. 8) for connecting the AIO 1 to the Internet.

For example, the left-hand operation button 30L for displaying the program listing is formed, as illustrated in FIG. 7, in such a manner that the operation portion 33a exposed on the side of the front surface has not a circular shape but a shape that an upper portion thereof is cut out. On the cutout portion, a word letting a user recognize a type of the operation button 30L is drawn. In this case, the word drawn on the cutout portion of the operation button 30L is “program listing”; for example, only a portion of the word is formed in outline letters on the periphery of the cover 3d colored in black as described above.

In this manner, by drawing the word “program listing” next to the operation button 30L, a user can easily recognize what the operation button 30L is for, so the operability can be improved and the convenience can be also improved. Incidentally, as in the example of the screen illustrated in FIG. 6, by touching an item 37 for each program with a user's finger, for example, watching or programmed recording of the program can be set.

In this case, the operation button 30L for displaying the “program listing” is set on the user's left-hand side of the AIO 1 in a state where the user sits face to face with the AIO 1, so that the user can touch a desired item 37 on the program listing with his/her right hand just after pressing the operation button 30L with his/her left hand. Many people are right-handed, so placing the operation button 30L on the left-hand side has an advantage in improving the operability.

Similarly, the right-hand operation button 30R for connection to the Internet s formed, as illustrated in FIG. 8, in such a manner that the operation portion 33a exposed on the side of the front surface has not a circular shape but a shape that an upper portion thereof is cut out. A word “Internet” is drawn on the cutout portion.

As described above, in the present embodiment, the push button mechanism 30 is provided, as an operation mechanism for receiving the pressing operation through the front surface 3e, on the frame 3c of the touch panel unit 3. Therefore, the push button mechanism 30 can be pressed more reliably as compared with the case where the push button mechanism is provided to the enclosure.

Especially, as in the present embodiment, in the configuration in which the touch panel unit 3 is vibrated by the vibrating mechanism, since the push button mechanism 30 is entirely integrated with the touch panel unit 3, generation of vibration or noise can be prevented advantageously.

In the present embodiment, the push button mechanism 30 is placed between the support positions where the frame 3c is supported by the plurality of swing supporting mechanisms 7. Therefore, the touch panel unit 3 is prevented from being tilted due to the pressing operation of the push button mechanism 30, and the push button mechanism 30 can be pressed more reliably.

In the present embodiment, the push button mechanism 30 has the circuit board 31 which is mounted on the back side of the front wall portion 3p of the frame 3c to be spaced from the front wall portion 3p; the push-button switch 32 which is provided to the circuit board 31 and placed on the back side of the front wall portion 3p; and the cover body 33 which covers the push-button switch 32, and penetrates through the through-hole 3v formed on the front wall portion 3p and is exposed on the front side of the frame 3c. Therefore, the push button mechanism 30 can be relatively easily fitted by using the frame 3c of the touch panel unit 3.

In the present embodiment, the swing supporting mechanism 7 has the elastic bushing 8 on which the through-hole 8a is formed and of which the periphery is fitted with any one of the enclosure 2 and the touch panel unit 3 (in the present embodiment, the enclosure 2 as an example), and further has the screw 9 which is connected to the other one out of the enclosure 2 and the touch panel unit 3 (in the present embodiment, the touch panel unit 3 as an example) via the connecting portion 7a penetrating through the through-hole 8a and holds the elastic bushing 8 together with the other one. Therefore, according to the present embodiment, the elastic bushing 8 can be fitted with any one of the enclosure 2 and the touch panel unit 3 (in the present embodiment, the enclosure 2), so that a worker can perform the assembly work more easily and smoothly as compared with the case of fitting the elastic body with an adhesive or a screw. Moreover, the elastic bushing 8 is placed so as to surround the connecting portion 7a, so it is possible to suppress a variation in swing characteristics (vibration characteristics) of the touch panel unit 3 in each direction perpendicular to the through-hole 8a. Furthermore, the elastic bushing 8 of which the periphery is supported by any one of the enclosure 2 and the touch panel unit 3 (in the present embodiment, the enclosure 2) is held between the other one (in the present embodiment, the touch panel unit 3) and the screw 9 connected to the other one, so it is easier to make a force of bounce of the elastic bushing 8 act equally in both directions of the axial direction of the through-hole 8a, and it is possible to suppress variations in swing characteristics (vibration characteristics) in the both directions.

In the present embodiment, the elastic bushing 8 of the swing supporting mechanism (connecting mechanism) 7 also works as a restraining module for preventing the touch panel unit 3 from swinging in an in-plane direction (a direction along the X-Y plane) and an out-of-plane direction (a direction intersecting with the X-Y plane, at least the Z direction, the front-back direction) of the front surface 3e. Namely, as illustrated in FIG. 2, the elastic bushing 8 is placed so as to surround the flange portion 2f provided as an example of a portion integrated into the enclosure 2, and portions integrated into the touch panel unit 3 (for example, the front wall portion 3p, the connecting portion 7a, and the head portion 9a) are placed so as to surround the elastic bushing 8; therefore, the elastic bushing 8 is held between the enclosure 2 and the touch panel unit 3 even if the touch panel unit 3 is displaced to any direction. Consequently, according to the present embodiment, excessive displacement of the touch panel unit 3 can be prevented or the displacement can be kept within a predetermined range by the elastic bushing 8 as a restraining module.

Further, according to the present embodiment, the mechanical operation buttons 30R and 30L are provided on the side of the front surface of the AIO 1, i.e., on a pair of the right and left vertical frame portions 3i of the frame 3c, respectively; therefore, a user interface can be provided on the side of the main body of the device, so the operability can be improved and the convenience can be also improved. For example, when a user presses the operation button 30L, which is assigned to work as a button for displaying a listing of programs, on the user's left-hand side of the AIO 1 in a state where the user sits face to face with the AIO 1, a listing of programs at the time can be displayed immediately. The user just touches a field of a program which he/she wants to watch out of those listed in the program listing, so that watching or programmed recording of the program can be easily set.

A control system of the AIO 1 is explained with reference to FIG. 9. As illustrated in FIG. 9, the control circuit 1150 of the AIO 1 comprises a CPU 1100 as a controlling body, a main memory 1101 such as a random access memory (RAM), a hard disk drive (HDD) 1119, the video-signal processing circuit 1120, a high-definition multimedia interface (HDMI)-signal processing module 1122, a remote-controller-signal receiving module 1123, a platform controller hub (PCH) 1110, a sound controller 1112, a BIOS-read only memory (ROM) 1113, an EC/KBC 1118, a speaker 1117, and the like. The AIO 1 further contains an audio video (AV) input terminal (not illustrated), a selector (not illustrated), an on-screen display interface (not illustrated), and the like.

The HDD 1119 is a storage medium for storing therein an operating system (OS), various application programs, and the like.

The CPU 1100 is a processor provided to control the operation of the AIO 1, and executes the OS, the various application programs, and the like which are loaded into the main memory 1101 from the HDD 1119.

The CPU 1100 also executes a system BIOS (Basic Input Output System) stored in the BIOS-ROM 1113. The system BIOS is a program for controlling hardware; the system BIOS is booted up in accordance with the power-on operation with respect to the power button 16 and controls various hardware, and provides basic input/output (I/O) means with respect to the hardware to the OS.

The PCH 1110 controls I/O devices, such as a Serial ATA, a USB, and a LAN.

The sound controller 1112 is a sound controller for controlling the speaker 1117.

The EC/KBC 1118 outputs a signal depending on the operations of the operation button 30R as a Home button, the operation button 30L as a keyboard button, and the power button 16. The CPU 1100 has a function of turning the power of the AIO 1 on or off depending on the operation of the power button 16.

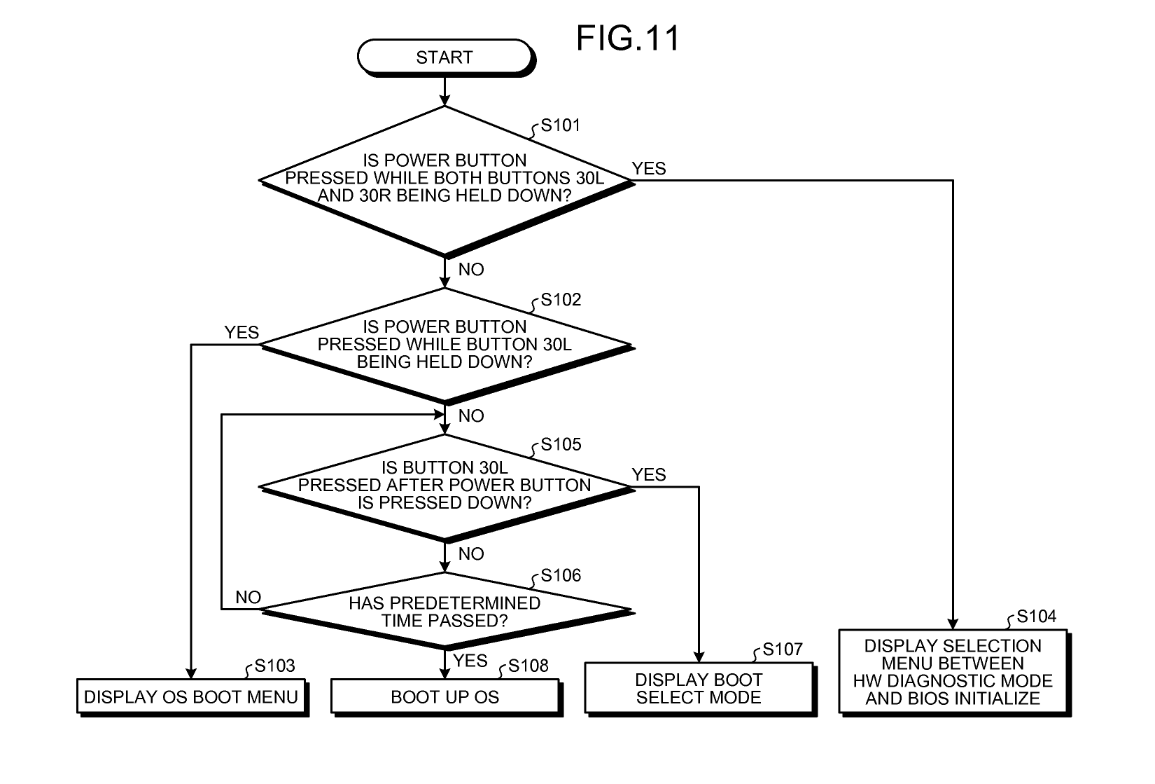

A characteristic function performed by the control circuit 1150 including the CPU 1100 and the EC/KBC 1118 in accordance with the system BIOS stored in the BIOS-ROM 1113 is explained with reference to FIGS. 10 and 11.

As illustrated in FIG. 10, the CPU 1100 operates in accordance with the system BIOS, thereby including a hardware control module 1200 working as a hardware control means and an OS-boot preprocessing module 1300 working as an OS-boot preprocessing means.

The hardware control module 1200 is activated in accordance with the power-on operation with respect to the power button 16, and provides basic input/output (I/O) means with respect to various hardware including the operation button 30L and the operation button 30R to the OS.

The OS-boot preprocessing module 1300 executes a process to be performed before the OS is booted up if a predetermined operation is made on at least any one of the operation button 30L and the operation button 30R within a predetermined time after the power-on operation with respect to the power button 16.

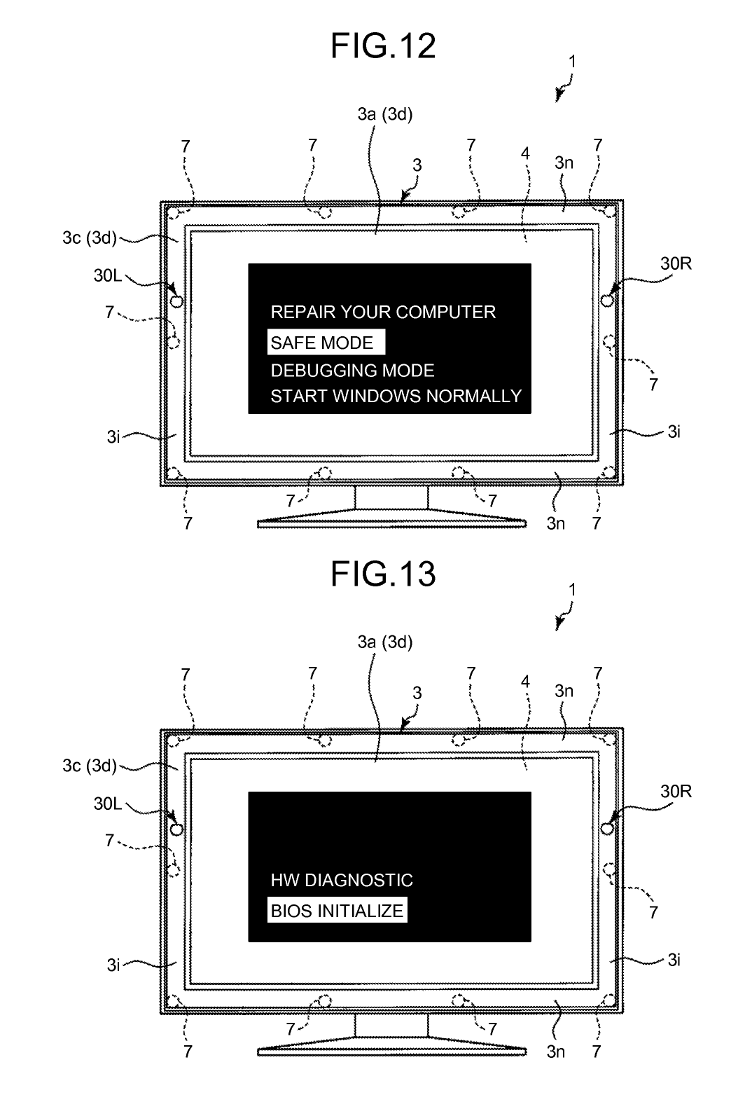

As illustrated in FIG. 11, when the EC/KBC 1118 determines that the power button 16 is pressed with the operation button 30L held down (NO at S101, YES at S102), the CPU 1100 displays an “OS boot menu” for setting the operation at the time of boot-up as illustrated in FIG. 12 on the display 4 via the video-signal processing circuit 1120 (S103: the OS-boot preprocessing module 1300).

In a state where the “OS boot menu” as illustrated in FIG. 12 is displayed, the operation button 30L works as a selection button. Namely, an operator presses the operation button 30L until a boot mode selected is highlighted in reverse video. On the other hand, in the state where the “OS boot menu” as illustrated in FIG. 12 is displayed, the operation button 30R works as an OK button. Namely, after confirming that the boot mode selected is highlighted in reverse video, the operator presses the operation button 30R to determine the selection.

In this manner, an operator just presses the operation button 30L and the power button 16 in a predetermined way, so that the AIO 1 according to the first embodiment can boot up the “OS boot menu” as illustrated in FIG. 12 and perform processing.

On the other hand, as illustrated in FIG. 11, when the EC/KBC 1118 determines that the power button 16 is pressed with both the operation button 30L and the operation button 30R held down (YES at S101), the CPU 1100 displays a “HW diagnostic mode/BIOS initialize menu” as illustrated in FIG. 13 on the display 4 via the video-signal processing circuit 1120 (S104: the OS-boot preprocessing module 1300). In the “HW diagnostic mode/BIOS initialize menu”, a selection menu for selecting any of “HW Diagnostic” and “BIOS Initialize” is displayed. The HW diagnostic mode is a mode to diagnose a status of hardware.

In a state where the “HW diagnostic mode/BIOS initialize menu” as illustrated in FIG. 13 is displayed, the operation button 30L works as a selection button. Namely, an operator presses the operation button 30L until a menu selected is highlighted in reverse video. On the other hand, in the state where the “HW diagnostic mode/BIOS initialize menu” as illustrated in FIG. 13 is displayed, the operation button 30R works as an OK button. Namely, after confirming that the menu selected is highlighted in reverse video, the operator presses the operation button 30R to determine the selection.

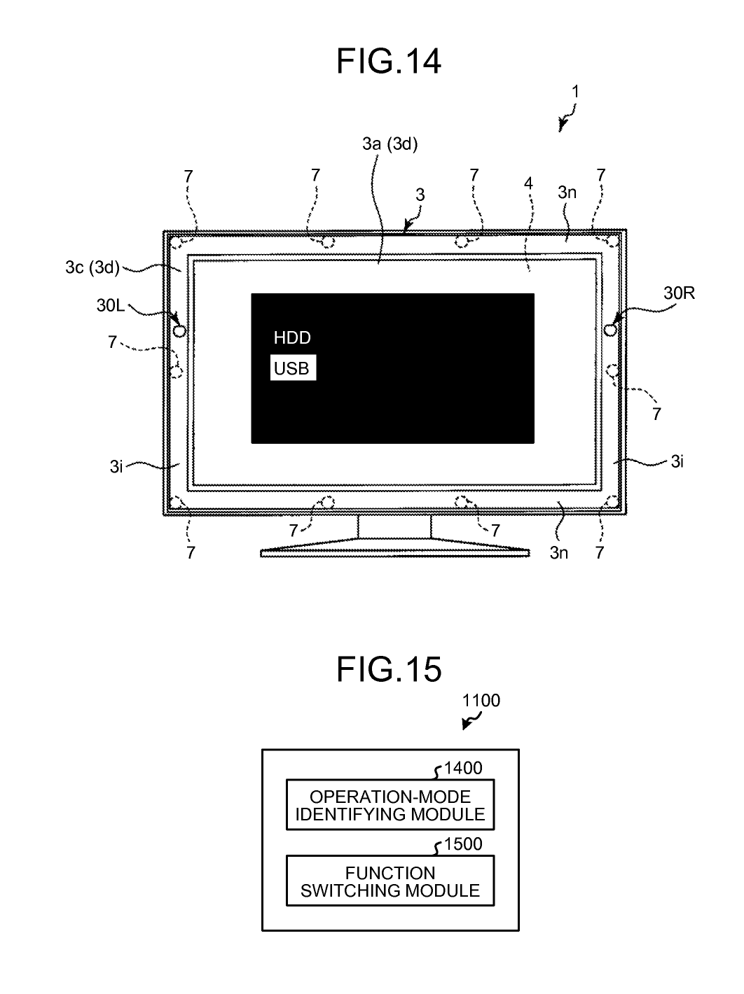

Furthermore, as illustrated in FIG. 11, when the EC/KBC 1118 determines that the operation button 30L is pressed within a predetermined time (for example, within 2 seconds) since the power button 16 was pressed down (NO at S101, NO at S102, YES at S105), the CPU 1100 displays a “boot select mode” for setting the selection of a boot disk as illustrated in FIG. 14 on the display 4 via the video-signal processing circuit 1120 (S107: the OS-boot preprocessing module 1300). In the “boot select mode”, a selection menu for selecting any of “internal hard drive (HDD)” and “external hard drive (USB)” is displayed.

In a state where the “boot select mode” as illustrated in FIG. 14 is displayed, the operation button 30L works as a selection button. Namely, an operator presses the operation button 30L until a hard drive selected is highlighted in reverse video. On the other hand, in the state where the “boot select mode” as illustrated in FIG. 14 is displayed, the operation button 30R works as an OK button. Namely, after confirming that the hard drive selected is highlighted in reverse video, the operator presses the operation button 30R to determine the selection.

Incidentally, as illustrated in FIG. 11, when the EC/KBC 1118 determines that the operation button 30L is not pressed within a predetermined time (for example, within 2 seconds) since the power button 16 was pressed (NO at S101, NO at S102, NO at S105, YES at S106), the CPU 1100 boots up the OS (S108).

After the boot-up of the OS, the operation button 30L is assigned to work as a button for displaying a program listing illustrated in FIG. 6, and the operation button 30R is assigned to work as a button for connecting the AIO 1 to the Internet. Namely, after the boot-up of the OS, the operation button 30L and the operation button 30R do not take over the control of the operation specification before the OS is booted up (the operation button 30L=Down Arrow Key (↓), the operation button 30R=Enter Key), and work as a user-arbitrarily-settable “programmable button” as a function selection on the OS.

In this manner, the AIO 1 according to the first embodiment achieves the following functions depending on how to press the operation button 30L, the operation button 30R, and the power button 16:

(1) Activation of the “OS boot menu”, the “HW diagnostic mode/BIOS initialize menu”, and the “boot select mode” before the OS is booted up is controlled.

(2) Before the OS is booted up, the operation button 30L works as a select function (Down Arrow Key (↓)) and the operation button 30R works as a determine function (Enter Key).

(3) After the OS is booted up, the operation button 30L and the operation button 30R work as a programmable button to control a valid function on the OS.

In this manner, the AIO 1 (the electronic device) according to the first embodiment, which is not equipped with a hardware keyboard, comprises at least one function button (the operation buttons 30L and 30R) for controlling a function defined on the OS, and can control a function within a BIOS control range of the main body of the AIO 1, a specific activation operation before the OS is booted up, selection of a function which can be arbitrarily set after the OS is booted up, and the like depending on how to press the operation buttons 30L and 30R in combination with the power button 16, a combination of the buttons, and the like.

A characteristic function performed by the control circuit 1150 including the CPU 1100 and the EC/KBC 1118 in accordance with the OS or application program stored in the HDD 1119 is explained with reference to FIGS. 15, 16, and 17.

As illustrated in FIG. 15, the CPU 1100 operates in accordance with the OS or application program, thereby including an operation-mode identifying module 1400 working as an operation-mode identifying means and a function switching module 1500 working as a function switching means.

The operation-mode identifying module 1400 identifies various modes of operation with respect to the operation buttons 30L and 30R working as function buttons.

The function switching module 1500 controls switching among a plurality of functions defined by the OS or an application running on the OS depending on the mode of operation identified by the operation-mode identifying module 1400.

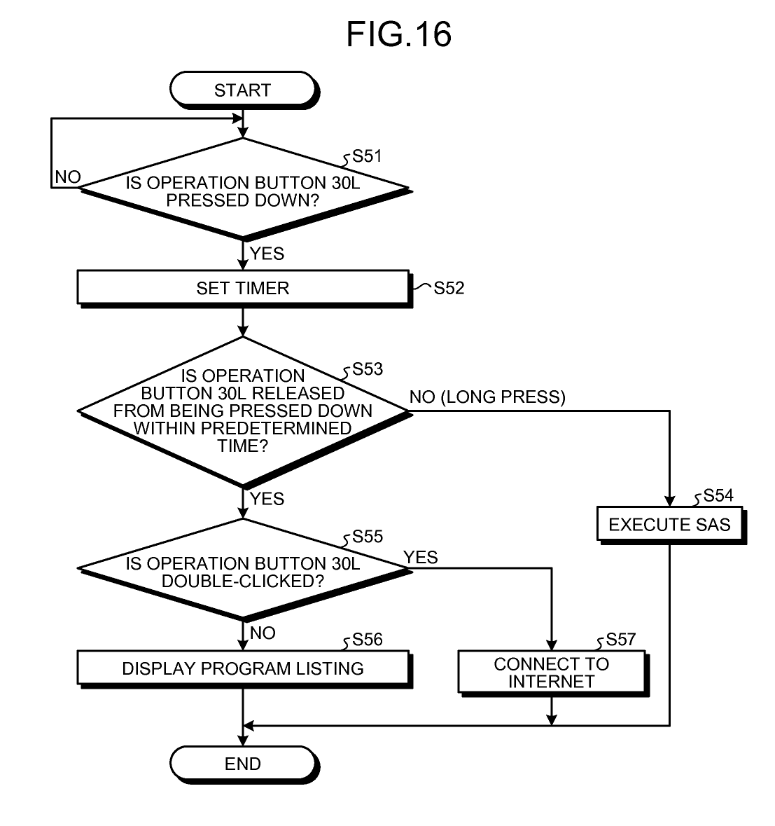

As illustrated in FIG. 16, when the operation button 30L is pressed down (YES at S51), the EC/KBC 1118 sets a timer (S52) and measures how long the operation button 30L will have been pressed down (for example, 4 seconds). Namely, at this time, whether the operation button 30L is pressed and held is determined.

When the operation button 30L is pressed and held (NO at S53: the operation-mode identifying module 1400), the EC/KBC 1118 deems the “CTRL”, “ALT”, and “DEL” keys provided to a typical keyboard are pressed at the same time and generates a scan code of “CTRL”+“ALT”+“DEL”, and the CPU 1100 executes a function called SAS (Secure Attention Sequence) for maintaining an application of the system or the like on the basis of the code generated by the EC/KBC 1118 (S54: the function switching module 1500). Consequently, for example, when an application makes no response, a user can open a menu by pressing and holding the operation button 30L and force-quit the non-responding application. Incidentally, in the AIO 1 according to the present embodiment, a time that the operation button 30L is deemed to be pressed and held is set to 4 seconds, so that execution of the SAS function can be made in the same sense as a force-quit of the power button 16 by pressing and holding the power button 16 (for 4 seconds or more).

On the other hand, when the operation button 30L is pressed for a short time just one time (YES at S53: the operation-mode identifying module 1400), the EC/KBC 1118 again sets the timer and determines whether it is a double click (S55).

When the EC/KBC 1118 determines that it is not a double click (NO at S55: the operation-mode identifying module 1400), the CPU 1100 displays, for example, the program listing illustrated in FIG. 6 (S56: the function switching module 1500).

On the other hand, when it is determined as a double click at S55 (YES at S55: the operation-mode identifying module 1400), the CPU 1100 executes a process for Internet connection (S57: the function switching module 1500).

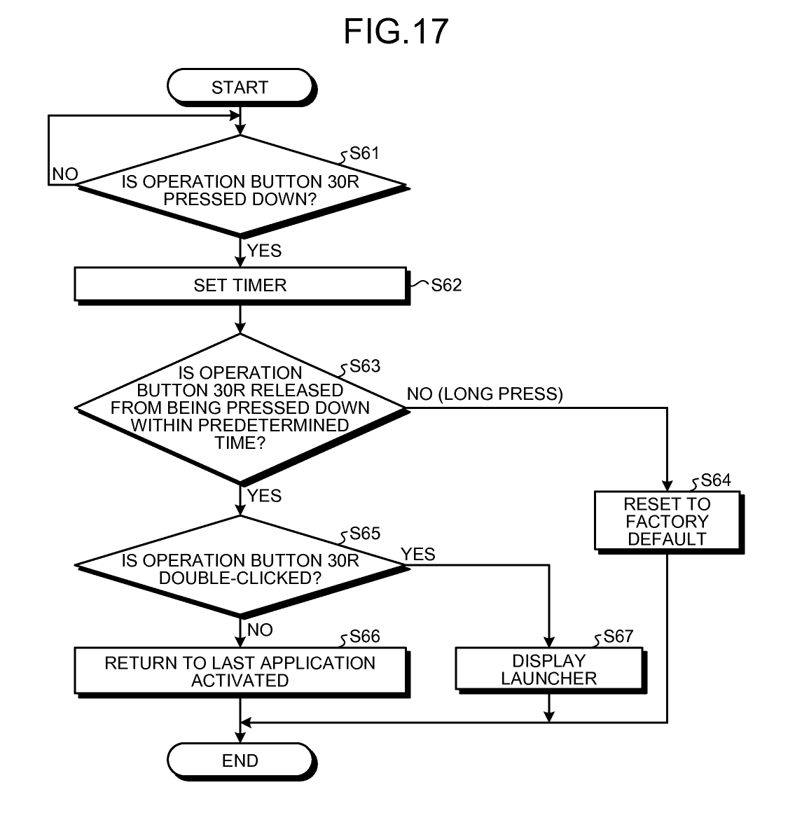

Subsequently, the operation, such as how the control circuit 1150 displays “launcher”, is explained with reference to FIG. 17.

As illustrated in FIG. 17, when the operation button 30R is pressed down (YES at S61), the EC/KBC 1118 sets a timer (S62) and measures how long the operation button 30R is pressed down (for example, 4 seconds). Namely, at this time, whether the operation button 30R is pressed and held is determined.

When the operation button 30R is pressed and held (NO at S63: the operation-mode identifying module 1400), the CPU 1100 resets the display setting to the factory default, “prerecorded display setting” (S64: the function switching module 1500). Consequently, for example, when a user has changed the display setting many times and cannot reset to the factory default, the user just presses and holds the operation button 30R, so that the display setting can be reset to the factory default.

On the other hand, when the operation button 30R is pressed for a short time just one time (YES at S63), the EC/KBC 1118 again sets the timer and determines whether it is a double click (S65).

When the EC/KBC 1118 determines that it is not a double click (NO at S65: the operation-mode identifying module 1400), the CPU 1100 returns to the last application activated by the AIO 1 (S66: the function switching module 1500).

On the other hand, when it is determined as a double click at S65 (YES at S65: the operation-mode identifying module 1400), the CPU 1100 displays a launcher displaying a list of the previously-registered files and programs which are represented by icons (S67: the function switching module 1500). Functions of the icons displayed in the launcher include a system lock function, a power plan select function, a display brightness adjust function, a wireless ON/OFF function, a sleep function, and the like.

In this manner, in the AIO 1 according to the present embodiment, the operation button 30L, the operation button 30R, and the power button 16 each can fulfill a different function from the original function by being pressed and held (for 4 seconds or more).

In this manner, in the AIO 1 according to the present embodiment, one button is used for a plurality of functions including the SAS function, so it is possible to achieve reduction in the number of parts, improvement of convenience for users, and improvement of design of the device.

Incidentally, in the AIO 1 according to the present embodiment, it is configured that the SAS function is performed when the operation button 30L is pressed and held; however, whether to execute the SAS function is not limited to depending on whether the operation button 30L is pressed long or short. Alternatively, the SAS function can be performed depending on either a single click or a double click or depending on a code pattern composed of a combination of short and long codes, such as a Morse code.

Incidentally, the system BIOS or application program executed by the AIO 1 according to the first embodiment can be provided by being recorded on a computer-readable recording medium, such as a CD-ROM, a flexible disk (FD), a CD-R, or a DVD, in an installable or executable file format.

Further, the system BIOS or application program executed by the AIO 1 according to the first embodiment can be stored on a computer connected to a network, such as the Internet, so as to provide the system BIOS or application program by being downloaded via the network. Moreover, the system BIOS or application program executed by the AIO 1 according to the first embodiment can be provided or distributed via a network, such as the Internet.

### Second Embodiment

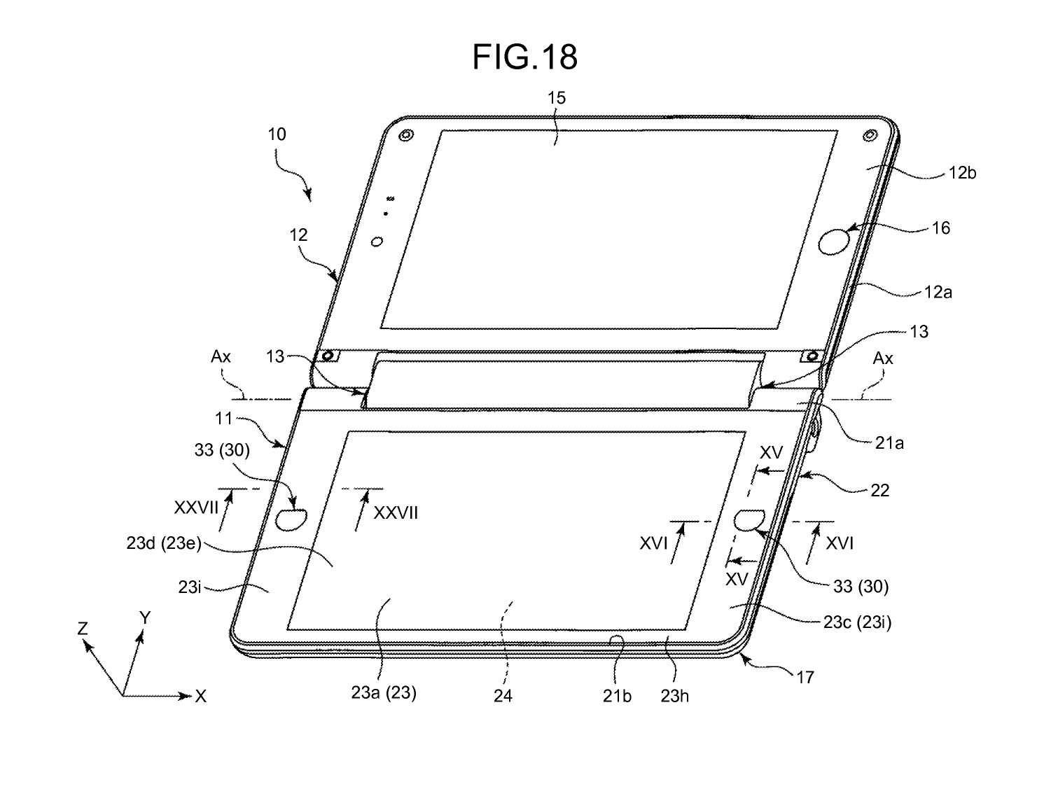

A second embodiment is explained with reference to FIGS. 18 to 46. The portions identical to those in the first embodiment described above are denoted by the same reference numerals.

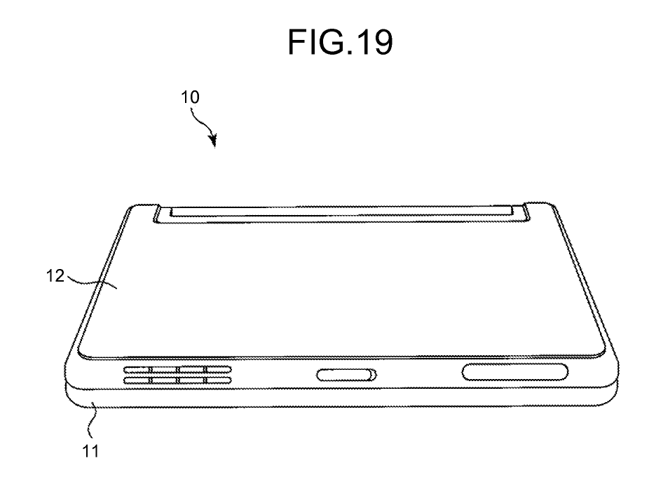

An electronic device 10 according to the present embodiment is, as illustrated in FIG. 18, a notebook personal computer, and comprises a rectangular flattened first main body portion 11 and a rectangular flattened second main body portion 12. The first main body portion 11 and the second main body portion 12 are rotatably connected to each other by a hinge mechanism 13 so that the first and second main body portions 11 and 12 can relatively rotate around a rotation axis Ax between an expanded state illustrated in FIG. 18 and a folded state illustrated in FIG. 19. Incidentally, in the present embodiment, for the sake of convenience in explanation, directions (an X direction, a Y direction, and a Z direction) are defined. The X direction and the Y direction are directions substantially along the surface of the first main body portion 11; the X direction is a width direction (a direction of a long side of the surface) of the first main body portion 11, and the Y direction is a depth direction (a direction of a short side of the surface) of the first main body portion 11. The Z direction is a direction perpendicular to the surface of the first main body portion 11 (a thickness direction of the first main body portion 11). The X, Y, and Z directions are perpendicular to one another. Incidentally, the electronic device 10 further comprises a tuner module (not illustrated).

As illustrated in FIG. 18, to the first main body portion 11, a display 24, the push button mechanism 30, and the like are provided in a condition that they are exposed on the side of a surface 21a as an outer surface of an enclosure 22. The display 24, such as an LCD, is provided as a display module and equipped with a touch panel 23a on the surface thereof. On the other hand, to the second main body portion 12, a display 15, such as an LCD, as a display module, the power button 16, and the like are provided in a condition that they are exposed on the side of a surface 12b as an outer surface of an enclosure 12a. In the expanded state illustrated in FIG. 18, the display 15, the display 24 equipped with the touch panel 23a, the cover body 33 of the push button mechanism 30, the power button 16, and the like are exposed on the outside and are in a condition that a user can use. On the other hand, in the folded state illustrated in FIG. 19, the surfaces 21a and 12b are opposed and in close contact with each other, and the displays 15 and 24, the cover body 33, the power button 16, and the like are hidden behind the enclosures 22 and 12a. Incidentally, in the present embodiment, as an example, only the first main body portion 11 has the touch panel 23a; alternatively, the second main body portion 12 can also has a touch panel. In the present embodiment, the touch panel 23a corresponds to a front panel, and the enclosure 22 corresponds to a supporting base.

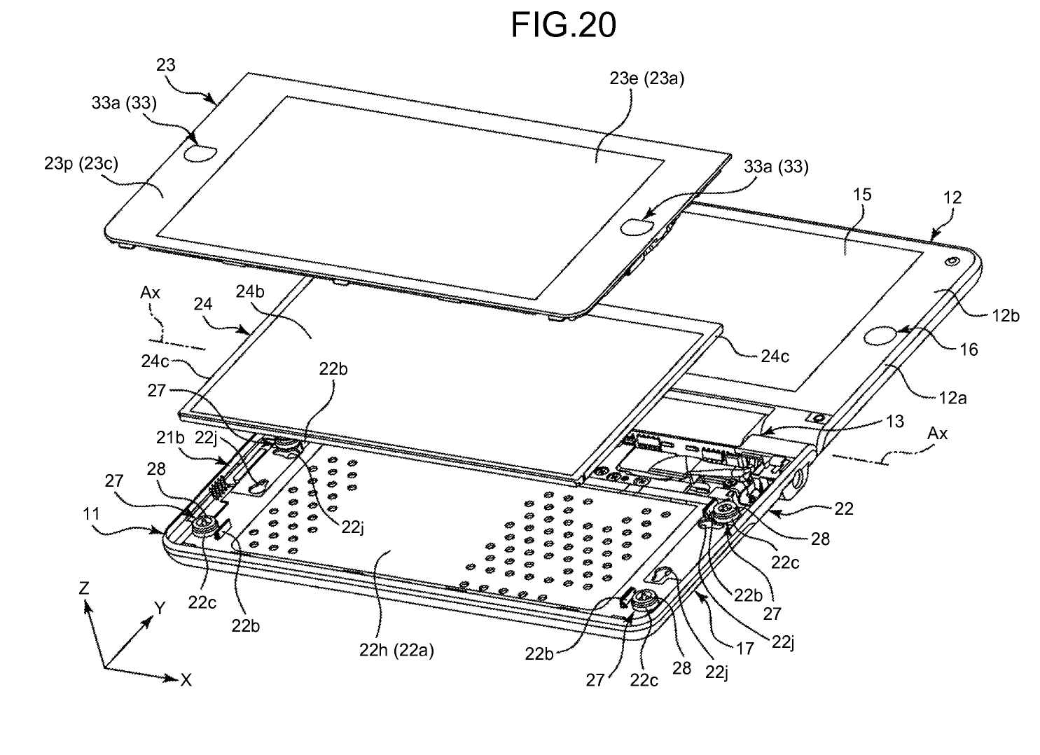

As illustrated in FIG. 20, in the present embodiment, the display 24 is placed on top of a bottom wall portion 22a of the enclosure 22 of the first main body portion 11, and a touch panel unit 23 is placed on top of the display 24. Incidentally, in the present embodiment, a front-back direction based on the display 24 is the Z direction, and the upper side and the lower side in FIGS. 18 and 20 are the front and the back, respectively. In the present embodiment, the touch panel unit 23 corresponds to a panel module.

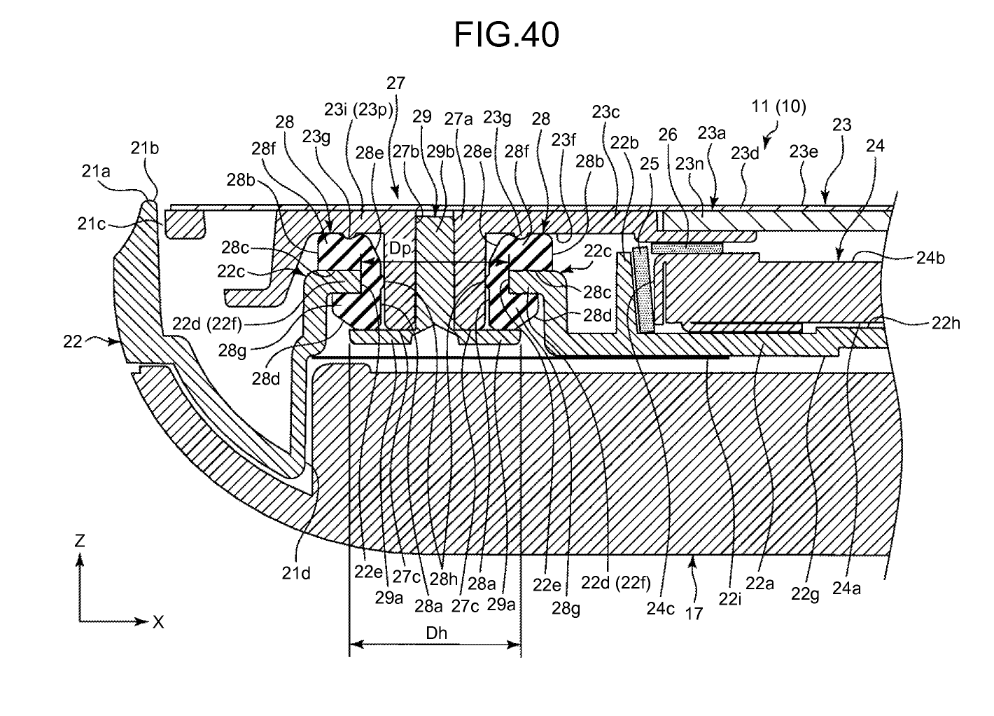

As illustrated in FIGS. 18 and 20, an opening portion 21b, which opens to the front (the upper side in the Z direction), is formed on the enclosure 22, and the opening portion 21b is covered with the touch panel unit 23. In the first main body portion 11, except for a peripheral portion on the side of the second main body portion 12 in which a portion of the hinge mechanism 13 is contained, there exists no front wall as a wall on the front side of the enclosure 22. The front of the first main body portion 11 is substantially formed by a front surface 23e of the touch panel unit 23. Incidentally, between the touch panel unit 23 and the opening portion 21b, an almost constant clearance 21c (see FIG. 40) is formed over the whole circumference of the touch panel unit 23.

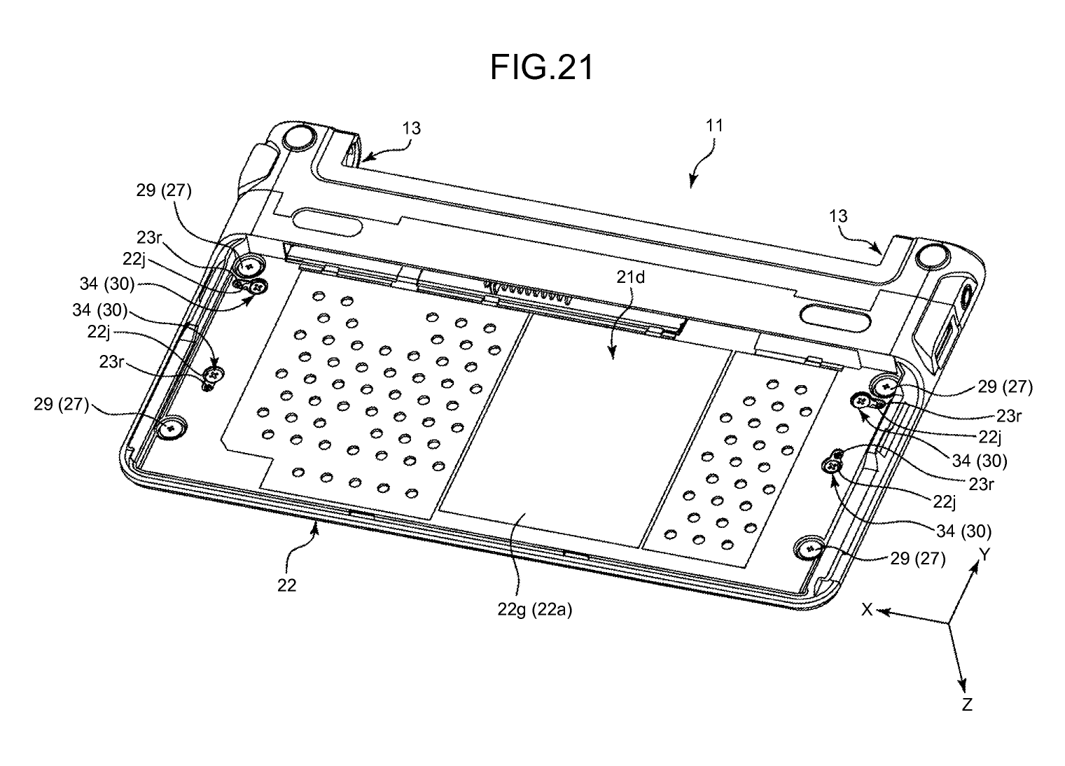

As illustrated in FIG. 21, on the side of the back surface of the enclosure 22 of the first main body portion 11, a concave portion 21d in which a flattened rectangular-solid-like battery pack 17 (see FIGS. 18, 20, 24, and 40) is fitted is formed. The concave portion 21d is formed on the side away from the hinge mechanism 13, i.e., the back side in the depth direction (the Y direction). A bottom surface of the concave portion 21d is a back surface 22g of the bottom wall portion 22a. Namely, in the present embodiment, the bottom wall portion 22a of the enclosure 22 works as a partition wall between an internal space of the enclosure 22 in which the display 24 and the touch panel unit 23 are contained and the concave portion 21d in which the battery pack 17 is contained. Incidentally, as illustrated in FIG. 40, the display 24 is fixed to the bottom wall portion 22a opposed to a back surface 24a with a screw (not illustrated) and the like.

A portion of the bottom wall portion 22a on which the display 24 is put on a front surface 22h thereof as illustrated in FIG. 20 and the battery pack 17 is placed on the back surface 22g thereof as illustrated in FIG. 21 projects forward to be located anterior to a portion on the side of the hinge mechanism 13 as illustrated in FIG. 20. The projecting portion is provided with a plurality of (in the present embodiment, four) longitudinal wall portions 22b. The longitudinal wall portion 22b is formed as a rib having a rectangular appearance when viewed from the side. The longitudinal wall portion 22b projects forward (upward in FIG. 20) from the bottom wall portion 22a, and is opposed to a side surface 24c which is a short side of the display 24. Also in the present embodiment, the longitudinal wall portions 22b can work as a positioning module when the display 24 is installed to the enclosure 22 and also an energy absorbing module, for example, when an impact load in the lateral direction acts on the display 24. Incidentally, in the present embodiment, two longitudinal wall portions 22b are placed to be opposed to one short side, i.e., one side surface 24c, and a total of four longitudinal wall portions 22b are provided on the bottom wall portion 22a.

As illustrated in FIG. 20, a bottomed-cylinder-like support bracket portion 22c composing a swing supporting mechanism 27 projects from the front surface 22h of the portion of the bottom wall portion 22a on which the display 24 is put on the front surface 22h thereof as illustrated in FIG. 20 and the battery pack 17 is placed on the back surface 22g thereof as illustrated in FIG. 21. In the present embodiment, a plurality of (in the present embodiment, four) support bracket portions 22c are placed on the outside of the longitudinal wall portions 22b in the width direction. An elastic bushing 28 is attached to each of the plurality of support bracket portions 22c.

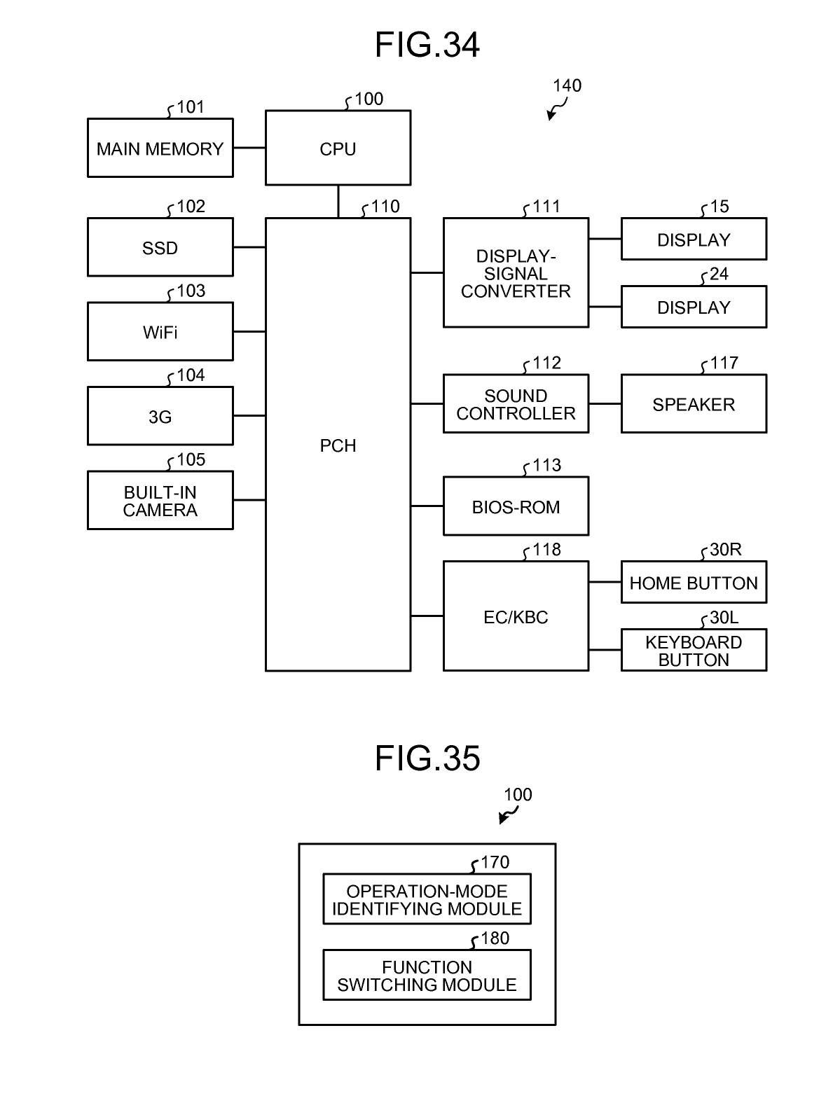

The display 24 is, as illustrated in FIG. 20, formed into a flattened rectangular solid. The display 24 receives a display signal from a control circuit 140 (see FIG. 34) which is composed of electronic parts and the like and mounted on a circuit board, and displays thereon an image, such as a still image or a moving image. Also in the present embodiment, a light representing the image displayed on a front surface 24b as a display screen of the display 24 passes through the clear transparent touch panel 23a and is projected forward.

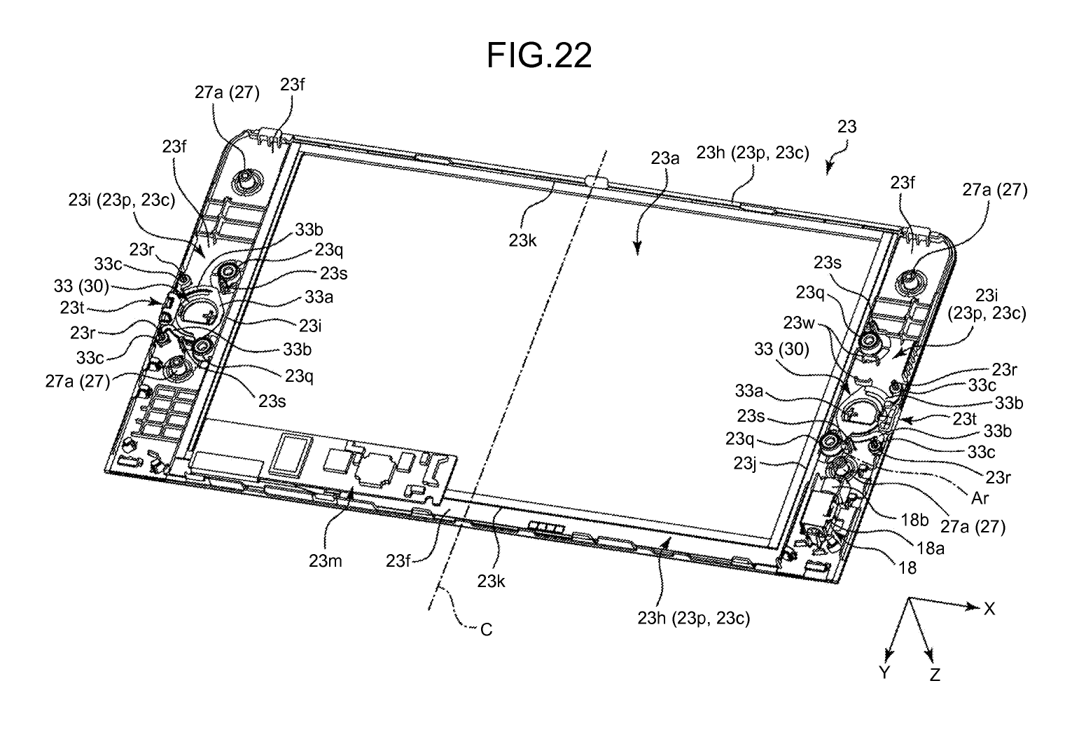

As illustrated in FIGS. 20, 22, and the like, the touch panel unit 23 has the touch panel 23a formed into a thin rectangular sheet and a rectangular frame-like frame 23c placed on the periphery of the touch panel 23a. The frame 23c is formed of a synthetic resin material, a metallic material, or the like. As illustrated in FIG. 40, the touch panel 23a and the frame 23c are attached to a transparent cover 23d formed of, for example, a thin sheet, film, or plate-like synthetic resin material or the like with a double-stick tape (not illustrated), an adhesive, or the like. The touch panel 23a and the frame 23c are integrated via the cover 23d. Furthermore, a peripheral portion 23n of the touch panel 23a is held between the frame 23c and the cover 23d. Incidentally, the periphery of the cover 23d is colored in, for example, black so as to prevent the peripheral portion 23n of the touch panel 23a and the frame 23c from coming out to the side of the front surface 23e of the touch panel unit 23 (the upper side in FIG. 40). Also in the present embodiment, as illustrated in FIG. 40, an elastic member 25 having the same function as the elastic member 5 described in the first embodiment and a seal member 26 having the same function as the seal member 6 described in the first embodiment are provided. In the present embodiment, the frame 23c corresponds to a frame member.

As illustrated in FIG. 20, the frame 23c has a rectangular frame-like and plate-like front wall portion 23p. Furthermore, as illustrated in FIG. 22, the frame 23c has, as a belt-like portion placed along the periphery of the touch panel 23a, horizontal frame portions 23h on the both sides in the depth direction and vertical frame portions 23i on the both sides in the width direction. In the present embodiment, a connecting portion 27a composing the swing supporting mechanism 27 is provided on a back surface 23f of the front wall portion 23p of the vertical frame portion 23i which is wider than the horizontal frame portion 23h. In the present embodiment, two connecting portions 27a for each of the two vertical frame portions 23i, i.e., a total of four connecting portions 27a are provided. Namely, in the present embodiment, the touch panel unit 23 is supported by four swing supporting mechanisms 27.

In the present embodiment, a vibrating mechanism 18 is provided on the back surface 23f of the front wall portion 23p of one of the two vertical frame portions 23i (in FIG. 22, the right-hand vertical frame portion 23i). In the present embodiment, the vibrating mechanism 18 has a motor 18a and an eccentric weight 18b which is rotated by the motor 18a. The center of gravity of the vibrating mechanism 18 is vibrated (rotated) by the rotation of the eccentric weight 18b driven by the motor 18a, and thereby a vibration is produced in the frame 23c and eventually the touch panel unit 23.

Here, as illustrated in FIG. 22, a rotation axis Ar of the motor 18a of the vibrating mechanism 18 extends along a short side 23j of a rectangle of the touch panel 23a from an anterior view. Therefore, a direction of vibration produced by the vibrating mechanism 18 is a direction perpendicular to the short side 23j, and the vibrating mechanism 18 can vibrate the touch panel unit 23 in a direction along a long side 23k. If the vibrating mechanism 18 vibrates the touch panel unit 23 in the direction along the short side 23j, i.e., in the Y direction, this makes it easier for the touch panel unit 23 to swing in the in-plane direction (i.e., within the X-Y plane) because there are increases in a distance between each of the connecting portions 27a as support points of the touch panel unit 23 and the vibrating mechanism 18 in the X direction (i.e., a moment arm) and a variation in the distance. In this case, a variation in vibration with location of the touch panel unit 23 is likely to increase. On this regard, in the present embodiment, a direction of vibration produced by the vibrating mechanism 18 is the direction perpendicular to the short side 23j, and the vibrating mechanism 18 vibrates the touch panel unit 23 in the direction along the long side 23k; therefore, a distance between each of the connecting portions 27a and the vibrating mechanism 18 in the Y direction (i.e., a moment arm) and a variation in the distance are reduced, and this makes it harder for the touch panel unit 23 to swing in the in-plane direction (i.e., within the X-Y plane). Namely, it is easier to obtain a vibration of the touch panel 23a along the long side having a smaller swing component (i.e., in the X direction).

The eccentric weight 18b of the vibrating mechanism 18 is placed on the side closer to the center of the short side 23j than the motor 18a. Therefore, a point of vibration produced by the vibrating mechanism 18 comes closer to the center of gravity of the touch panel unit 23, so the touch panel unit 23 can be vibrated more efficiently. Moreover, the touch panel unit 23 is less likely to swing in the in-plane direction (i.e., within the X-Y plane) as compared with the case where the eccentric weight 18b is placed at the position farther away from the center of the short side 23j than the motor 18a. Namely, it is easier to obtain a vibration along the long side having a smaller swing component (i.e., in the X direction).

As described above, in the present embodiment, while the battery pack 17 is placed on the farther side (i.e., the back side in the depth direction) than the hinge mechanism 13, the vibrating mechanism 18 is placed on the nearer side (i.e., the front side in the depth direction) than the hinge mechanism 13. Namely, in the present embodiment, the battery pack 17 and the vibrating mechanism 18 are placed efficiently without interference with each other in the enclosure 22 of the first main body portion 11.

As in the present embodiment, the battery pack 17 is placed on the side farther away from the hinge mechanism 13, thereby making the relatively-heavy battery pack 17 work as a means to prevent the electronic device 10 from falling. That is, for example, when the second main body portion 12 in the state illustrated in FIG. 18 is bent forward around the rotation axis Ax of the hinge mechanism 13 with respect to the first main body portion 11 of the electronic device 10, and the second main body portion 12 is placed to be at an obtuse angle to the first main body portion 11 (the X-Y plane), the battery pack 17 is away from the rotation axis Ax, so the second main body portion 12 can be prevented from falling.

As illustrated in FIG. 22, also in the present embodiment, the push button mechanism 30 as an operation mechanism is placed on the back surface 23f of the front wall portion 23p of the vertical frame portion 23i of the frame 23c. In the present embodiment, the push button mechanism 30 is set on the center of the vertical frame portion 23i in the longer direction (the Y direction), and the connecting portions 27a, i.e., the swing supporting mechanisms 27 are placed on the both sides of the vertical frame portion 23i in the longer direction across the push button mechanism 30. The cover body 33 and the connecting portions 27a (i.e., the swing supporting mechanisms 27) as movable portions of the push button mechanism 30 are symmetrically placed with respect to a center line C which passes through of the center of the touch panel unit 23 in the X direction and extends along the Y direction.

On the back surface 23f of the front wall portion 23p of the horizontal frame portion 23h of the frame 23c on the side of the hinge mechanism 13, a circuit board 23m on which electronic parts for processing the touch panel 23a are mounted is placed. The circuit board 23m is placed on the side close to the vertical frame portion 23i (the left-hand vertical frame portion 23i in FIG. 22) on the side opposite to the vertical frame portion 23i provided with the vibrating mechanism 18 (the right-hand vertical frame portion 23i in FIG. 22).

Also in the present embodiment, as illustrated in FIGS. 18 and 22, etc., the push button mechanism 30 is provided to each of the right and left-hand vertical frame portions 23i of the frame 23c which extend in the up-down direction like belts. Furthermore, the push button mechanism 30 is placed between a plurality of (in the present embodiment, two) support positions where the frame 23c is supported by the swing supporting mechanisms 27.

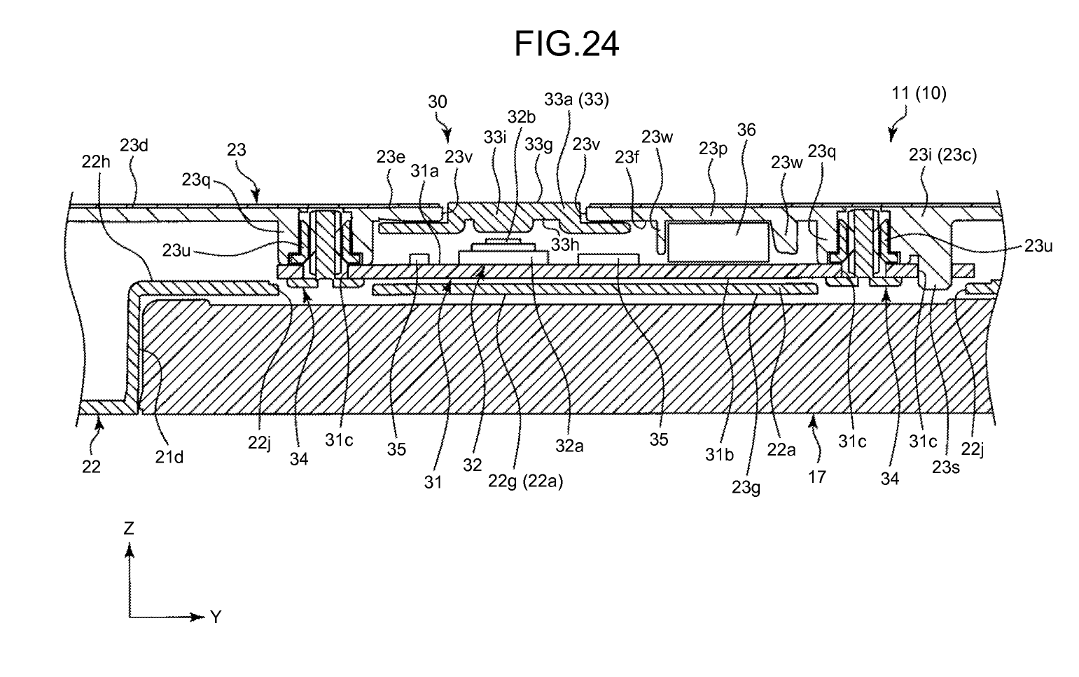

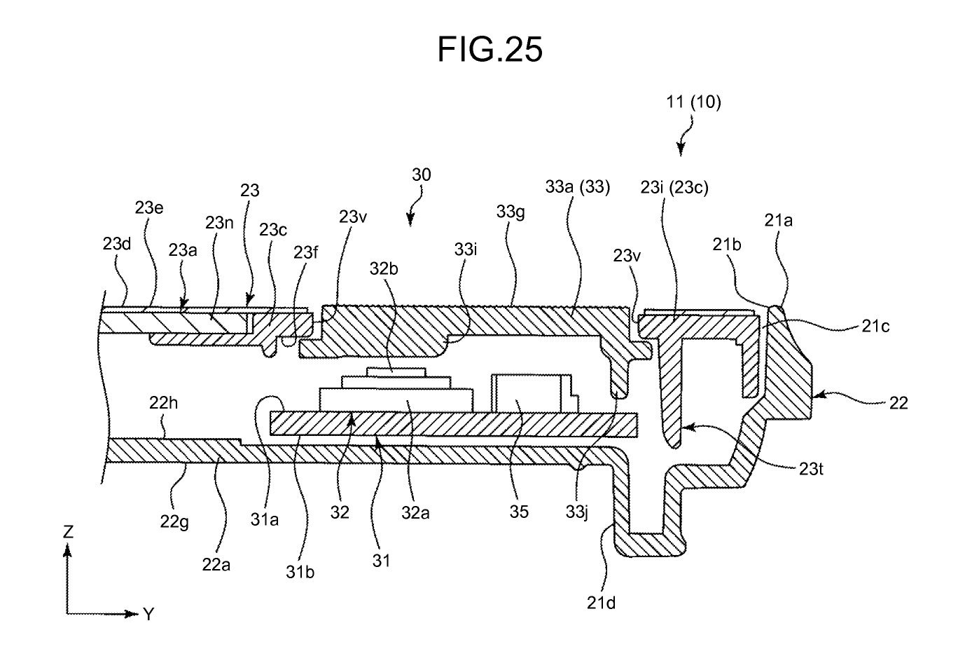

Further, also in the present embodiment, as illustrated in FIGS. 24 and 25, etc., the push button mechanism 30 has the circuit board 31 as an operation mechanism supporting member, the push-button switch 32 mounted on the circuit board 31, and the cover body 33 for covering the push-button switch 32.

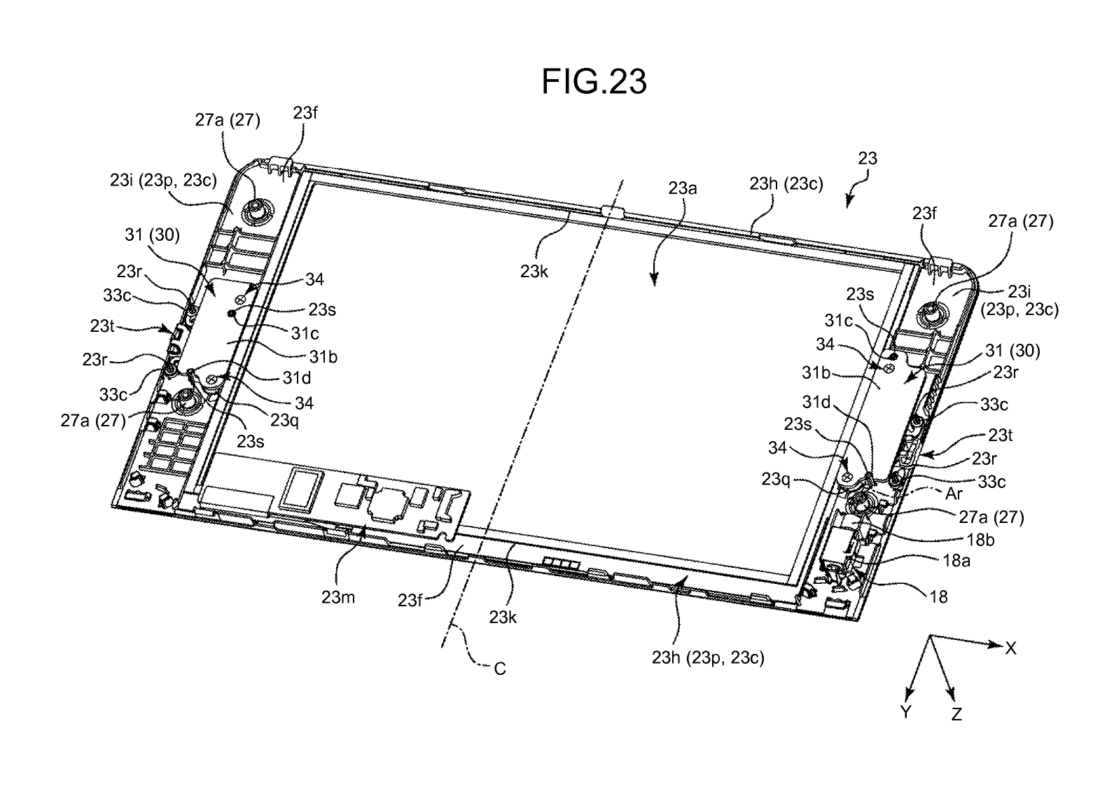

Moreover, also in the present embodiment, as illustrated in FIGS. 23 to 25, the circuit board 31 is placed on the back side of the front wall portion 23p of the frame 23c to be spaced from the front wall portion 23p and parallel to the front wall portion 23p. Namely, the circuit board 31 is placed in a posture that the front surface 31a is directed forward and the back surface 31b is directed backward.

As illustrated in FIGS. 22 and 24, etc., on the front wall portion 23p of the frame 23c, a boss portion 23q projecting backward is provided as a supporting-member fixing module. A plurality of (in the present embodiment, two for each push button mechanism 30) boss portions 23q are provided at intervals along the peripheral portion 23n of the touch panel 23a (see FIG. 25). Each of the boss portions 23q is fitted with a tubular female screw member 23u by insert molding or the like. The screw 34 penetrating through the through-hole 31c of the circuit board 31 is inserted into the female screw member 23u and tightened, thereby the circuit board 31 is fixed to the boss portion 23q as illustrated in FIG. 23. Furthermore, on the front wall portion 23p, a projection portion 23s projecting backward is provided. The projection portion 23s and the adjacent boss portion 23q are integrated via a rib or the like.

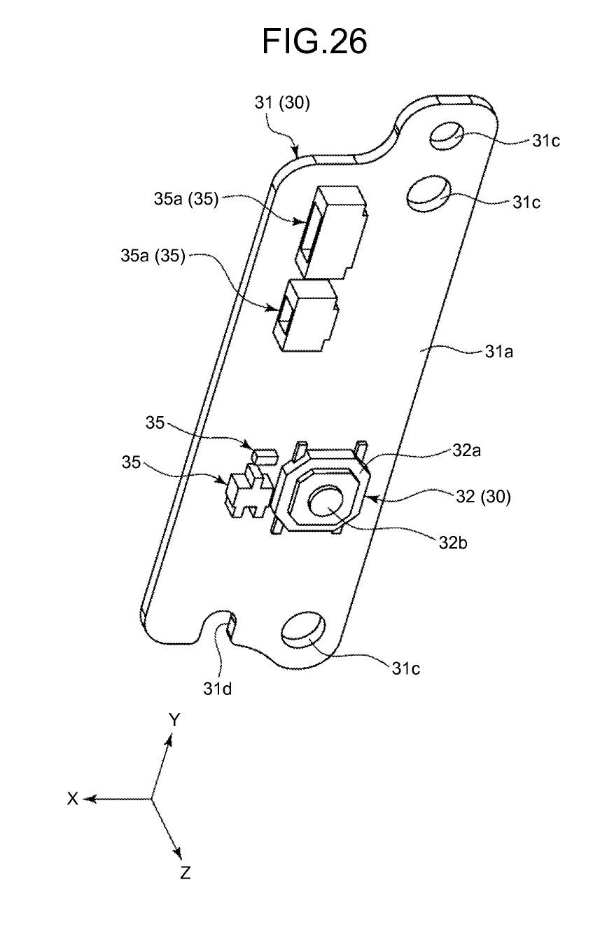

Also in the present embodiment, the circuit board 31 is configured as a printed circuit board. As illustrated in FIG. 26, on the front surface 31a of the circuit board 31 opposed to the back surface 23f of the front wall portion 23p, the push-button switch 32, parts 35, and the like are mounted by soldering or the like. The push-button switch 32 is connected to a control circuit 140 (see FIG. 34) including a CPU and the like via a wiring pattern (not illustrated) formed on the circuit board 31, a connector 35a as one of the parts 35 mounted on the circuit board 31, a harness (not illustrated) connected to the connector 35a, and the like. On the circuit board 31, the through-hole 31c through which the projection portion 23s and the screw 34 penetrate and a notch 31d are formed. The projection portion 23s, the through-hole 31c through which the projection portion 23s penetrates, and the notch 31d work as a positioning module for positioning the circuit board 31.

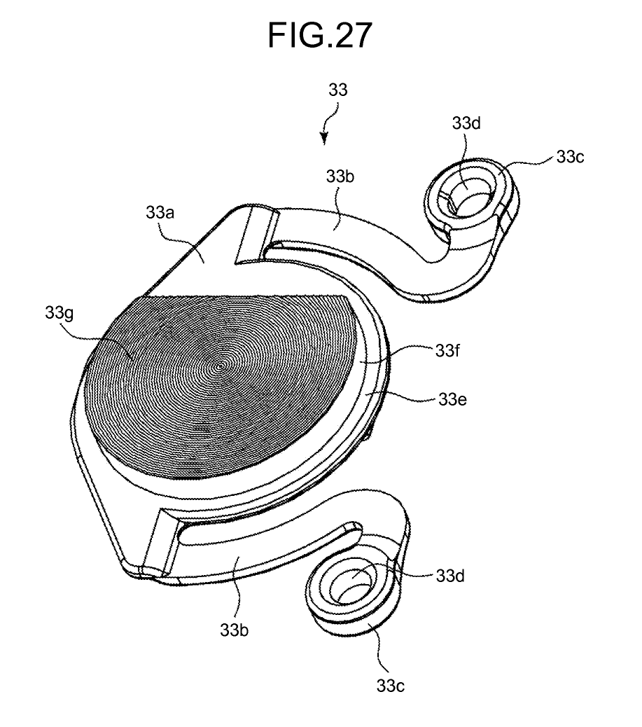

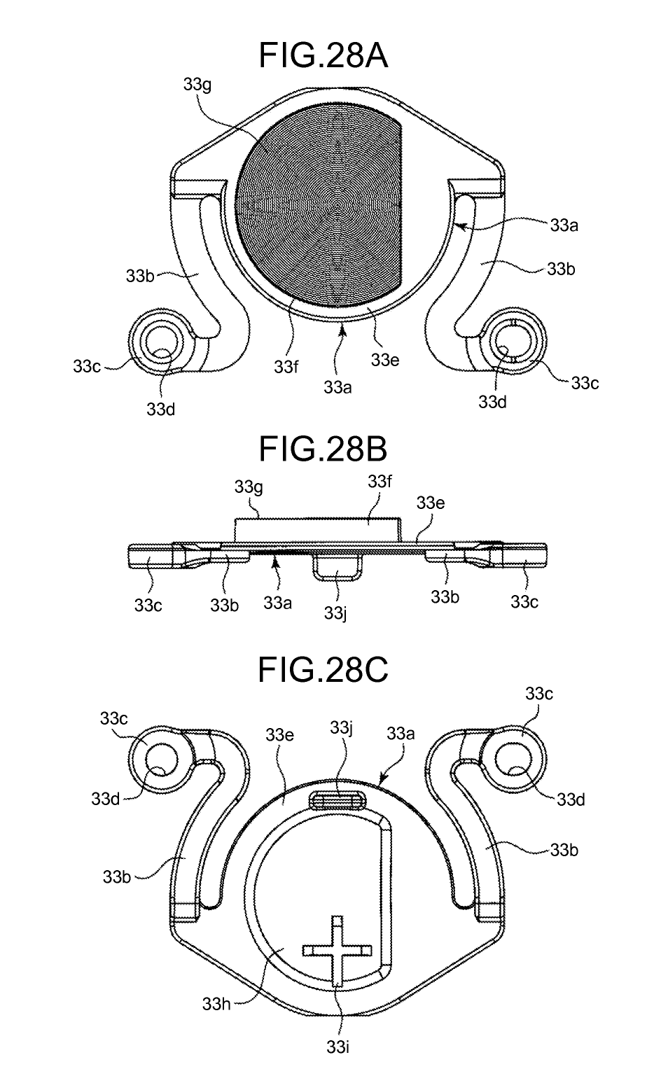

As illustrated in FIGS. 24 and 25, the cover body 33 covers the front of the push-button switch 32 at a distance. The cover body 33 is formed of an elastic body containing elastomer, synthetic resin, or the like. As illustrated in FIGS. 27 and 28, the cover body 33 has the operation portion 33a, an arm portion 33b, and a fixed portion 33c. As illustrated in FIGS. 22 and 23, on the back surface 23f of the front wall portion 23p, a projection portion 23r is provided as a cover-body fixing module. In a state where the projection portion 23r is inserted into a through-hole 33d formed on the fixed portion 33c, the fixed portion 33c is fixed to the projection portion 23r and the back surface 23f of the front wall portion 23p by welding, adhesive bonding, or the like, thereby the cover body 33 is fixed to the frame 23c. In the present embodiment, the cover body 33 is fixed to the frame 23c via two fixed portions 33c. Two projection portions 23r corresponding to the two fixed portions 33c are, as illustrated in FIG. 22, placed at an interval between them along the depth direction (the Y direction) of the enclosure 22. Namely, in the present embodiment, the cover body 33 is supported by the frame 23c at both ends in the depth direction of the enclosure 22 and one end in the width direction.

The operation portion 33a is formed into a substantially a disk shape. Out of the belt-like arm portion 33b extending between the fixed portion 33c and the operation portion 33a, a portion approaching the operation portion 33a from the fixed portion 33c and a portion extending along the periphery of the operation portion 33a in an arc are connected and form a V shape. The arm portion 33b is curved in this manner, thereby the length of the arm portion 33b is increased, and a stress generated in the operation portion 33a can be prevented from increasing. Incidentally, it is preferable that the arm portion 33b is assured of stiffness enough to resist movement of the operation portion 33a in a state where a pressing force or the like does not act on the operation portion 33a, however, the gravity and a predetermined vibration input force act on the operation portion 33a.

The operation portion 33a has a ring-like and plate-like base portion 33e and a bulging portion 33f having a D-shaped cross-section which cylindrically bulges forward from the center of the base portion 33e. On the side of the rear surface 33h of the bulging portion 33f, a concave portion is formed. Furthermore, on the side of the rear surface 33h of the operation portion 33a, the projection portion 33i opposed to the movable portion 32b and the projection portion 33j opposed to the front surface 31a of the circuit board 31 at the position away from the movable portion 32b are provided. As illustrated in FIGS. 24 and 25, the projection portion 33i is placed in front of (in FIGS. 24 and 25, above) the movable portion 32b of the push-button switch 32 in a state where the cover body 33 is assembled, and is opposed to the movable portion 32b at a distance. When the cover body 33 is pressed backward with a user's finger or the like, the projection portion 33i thrusts the movable portion 32b. In the same manner as in the first embodiment, the projection portion 33j has contact with the front surface 31a of the circuit board 31 when the operation portion 33a is pressed with a user's finger or the like at the position away from the push-button switch 32 (for example, a right-hand end portion of the operation portion 33a in FIG. 25), and works as a supporting strut. Namely, also in the present embodiment, the projection portion 33j corresponds to a tilt preventing portion. Incidentally, as illustrated in FIG. 28C, in the present embodiment, the projection portion 33i is formed into a cross shape in cross-section. This prevents an occurrence of sink in molding.

As illustrated in FIGS. 24 and 25, a through-hole 23v is formed on the front wall portion 23p. The bulging portion 33f of the operation portion 33a of the cover body 33 penetrates through the through-hole 23v, and is exposed on the side of the front surface 23e of the touch panel unit 23. In the present embodiment, the top surface 33g of the operation portion 33a and the front surface 23e of the touch panel unit 23 are set on about the same level. When the cover body 33 is pressed from the front side thereof with a user's finger or the like, the cover body 33 elastically deforms and bends backward (the lower side in FIGS. 24 and 25), and the operation portion 33a sinks beneath the front surface 23e; when the cover body 33 is released from being pressed, the cover body 33 returns forward and is back in an initial state.

As illustrated in FIG. 22, in the present embodiment, the plurality of (two, in the present embodiment) boss portions 23q are placed on the both sides of the vertical frame portion 23i, which is a belt-like portion, in the extending direction (i.e., the Y direction) across the cover body 33. This makes it easier to form the vertical frame portion 23i to be smaller in width.

In the present embodiment, the boss portions 23q are placed on the side of one end of the vertical frame portion 23i in the width direction, and the projection portions 23r are placed on the side of the other end of the vertical frame portion 23i in the width direction. Consequently, the boss portions 23q and the projection portions 23r are efficiently placed on the vertical frame portion 23i, and this makes it easy to prevent the size of the vertical frame portions 23i and eventually the touch panel unit 23 from increasing.

In the present embodiment, the boss portions 23q are placed at the position closer to the touch panel 23a than the projection portions 23r. Namely, the circuit board 31 is installed on the side of the base end of the vertical frame portions 23i which is close to the touch panel 23a and has the higher stiffness, so the circuit board 31 and eventually the push-button switch 32 can be supported more stably by the vertical frame portions 23i.

In the present embodiment, as illustrated in FIGS. 22 and 23, a projection portion 23t with a hook is provided as a harness holding portion at the position between a pair of the projection portions 23r on the back surface 23f of the vertical frame portion 23i. This can prevent the harness from interfering with the operation portion 33a and the arm portion 33b of the cover body 33.

In the present embodiment, as illustrated in FIG. 24, a magnet 36 is provided on the back surface 23f of the front wall portion 23p, and the circuit board 31 covers the back side of the magnet 36. The magnet 36 is an object to be detected by a hall element (not illustrated) as a magnetic sensor for detecting an open or close state of the first main body portion 11 and the second main body portion 12. The hall element is built into the second main body portion 12. The magnet 36 is attached to the back surface 23f of the front wall portion 23p by adhesive bonding or the like. In such a configuration, even if the magnet 36 comes off from the back surface 23f for any cause, the circuit board 31 can prevent the magnet 36 from moving to another position in the enclosure 22. Incidentally, on the back surface 23f of the front wall portion 23p, a projection portion 23w is provided to restrict lateral movement of the magnet 36 and to work as a guide at the time of attachment. Alternatively, the magnet 36 as a part can be mounted on the circuit board 31.

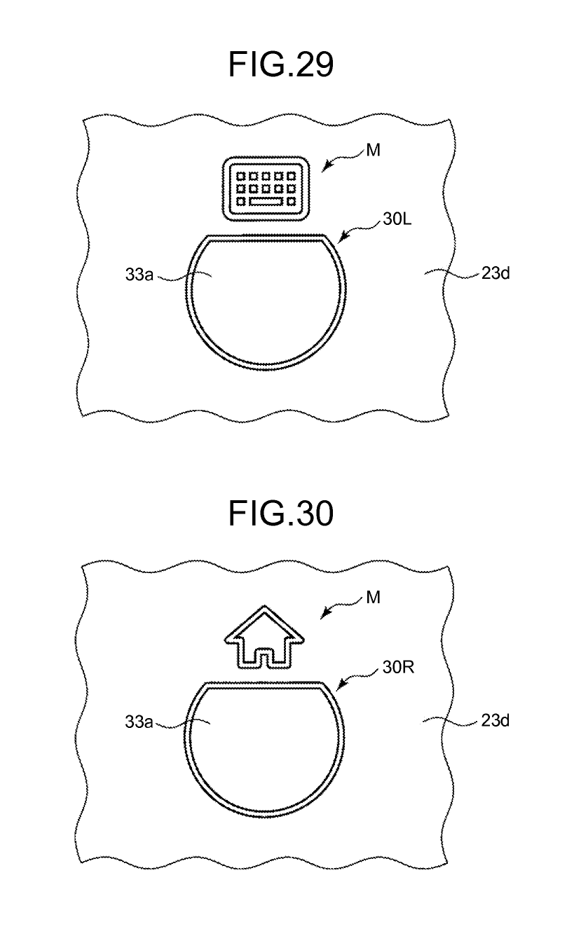

FIG. 29 illustrates a partial enlarged external view of the left-hand push button mechanism 30 of the first main body portion 11 illustrated in FIG. 18. FIG. 30 illustrates a partial enlarged external view of the right-hand push button mechanism 30 of the first main body portion 11 illustrated in FIG. 18. In the present embodiment, the left-hand push button mechanism 30 illustrated in FIG. 29 is assigned to work as the operation button 30L for displaying a keyboard to be described below. Furthermore, in the present embodiment, the right-hand push button mechanism 30 illustrated in FIG. 30 is assigned to work as the operation button 30R for returning to the last application activated by the electronic device 10.

For example, the left-hand push button mechanism 30 for displaying a keyboard has the operation portion 33a exposed on the side of the surface 21a of the enclosure 22 of the first main body portion 11, and the operation portion 33a is formed into not a circle but a D-shape in cross-section that a portion of the operation portion 33a on the side of the hinge mechanism 13 (the upper side in the drawing) is cut out. On the cutout portion of the cover 23d on the side of the surface of the enclosure, a mark M for letting a user recognize a type of the operation button 30L is made. In this case, the mark M made on the cutout portion of the operation button 30L is a simplified illustration of a keyboard, and, for example, as described above, the mark M is highlighted in reverse video on the periphery of the cover 23d colored in black, etc.

In this manner, by making the “keyboard” mark M next to the operation button 30L, a user can easily recognize what the operation button 30L is for, so the operability can be improved and the convenience can be also improved. Especially, the operation portion 33a is formed into a D-shape in cross-section and the cutout portion is formed, and the mark M is made on the cutout portion, so the operation button can look well-organized and simple, and the design can be improved.

Similarly, as for the right-hand operation button 30R working as the Home key, as illustrated in FIG. 30, the operation portion 33a exposed on the side of the surface 21a of the enclosure 22 is formed into not a circle but a D-shape in cross-section that a portion of the operation portion 33a on the upper side in the drawing is cut out. On the cutout portion, a simplified illustration of a “home” is drawn to let a user recognize the operation button 30R is for “Home”.

As described above, the two operation buttons 30R and 30L provided on the right and left sides of the first main body portion 11 are symmetrically placed with respect to the center line C illustrated in FIG. 22, so the operation buttons 30R and 30L are well-balanced and look well. Especially, portions of the respective operation portions 33a, which are exposed on the surface 21a, of the two operation buttons 30L and 30R on the side of the hinge mechanism 13 are cut out, and the respective marks M are made on the cutout portions, i.e., next to the operation buttons 30L and 30R, so the up-down direction of the operation buttons can be easily recognized. In other words, the cutout portions of the operation buttons 30L and 30R produce a lead for a user to easily recognize the direction of the electronic device 10. Especially, the electronic device 10 of the present embodiment can operate in a dual mode in which an image is displayed on both the first main body portion 11 and the second main body portion 12, so making it easy to recognize the direction is important in improving the convenience.

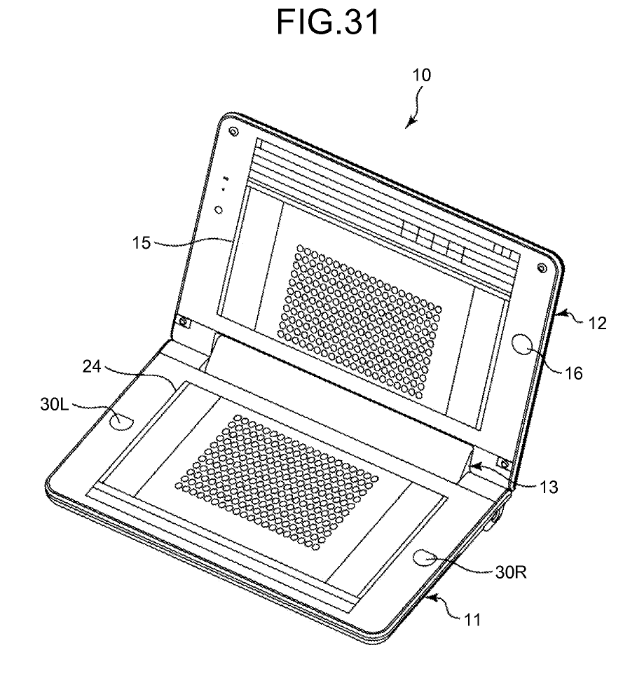

FIG. 31 illustrates an example of a dual-mode screen on which one image is displayed with the display 24 of the first main body portion 11 and the display 15 of the second main body portion 12. Incidentally, in this example, there is illustrated a state where the first main body portion 11 is put on the horizontal plane, such as a desk, and the second main body portion 12 is set up on the user side, i.e., in a standing position via the hinge mechanism 13. Namely, in the example illustrated in FIG. 31, the two displays 15 and 24 arranged one above the other are used as one display. As another example of use of the dual-mode screen, the display 24 of the first main body portion 11 and the display 15 of the second main body portion 12 can be used by arranging them side by side (in the lateral direction). Specifically, a user holds the first main body portion 11 in his/her left hand and the second main body portion 12 in his/her right hand.

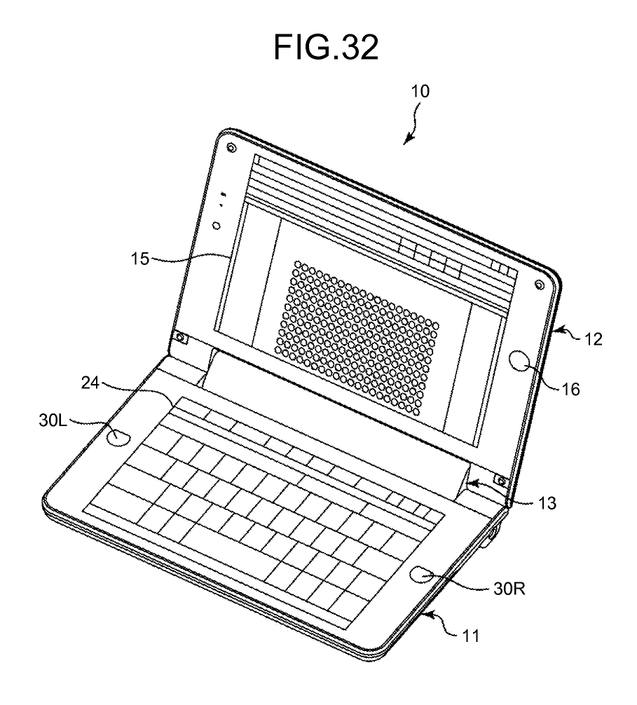

When a user clicks the above-mentioned operation button 30L for displaying a keyboard in the state illustrated in FIG. 31 with his/her left-hand finger, an image on the display 24 of the first main body portion 11 is switched to a keyboard image illustrated in FIG. 32. In the state illustrated in FIG. 32, i.e., the state where the display 24 displays thereon the keyboard image, when the user clicks the operation button 30L, the image on the display 24 is switched to the dual-mode screen illustrated in FIG. 31.

Incidentally, in the state where the keyboard image is displayed illustrated in FIG. 32, if the user touches a button of the displayed keyboard, a key input operation is performed. Namely, in this state, the electronic device 10 works as a so-called notebook personal computer. As is obvious, for example, a text in the image displayed on the display 15 of the second main body portion 12 can be edited by the key input operation.

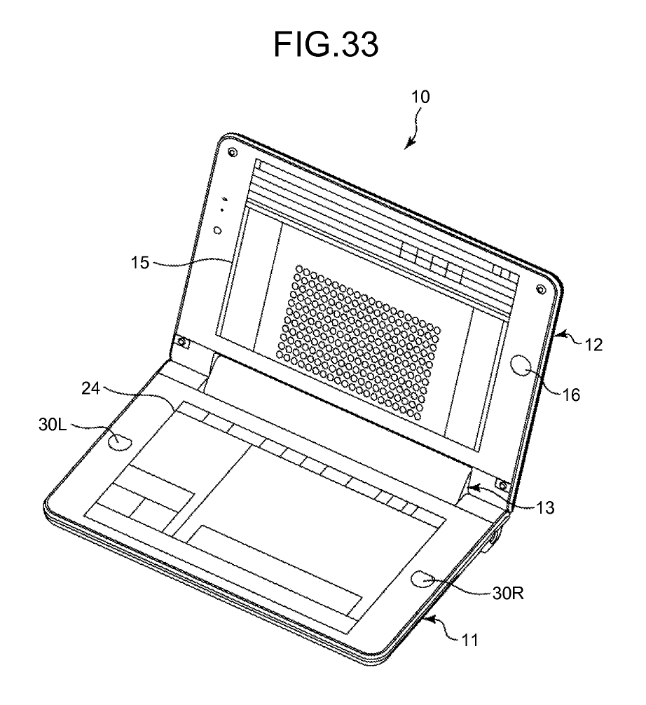

In the state of the dual-mode screen illustrated in FIG. 31, when the user double-clicks the operation button 30L, the image on the display 24 of the first main body portion 11 is switched to a mousepad image illustrated in FIG. 33. Moreover, in the state where the mousepad image is displayed as illustrated in FIG. 33, when the user double-clicks the operation button 30L, the image on the display 24 is switched to the dual-mode screen illustrated in FIG. 31.

In this manner, the operation button 30L used for displaying the “keyboard” or the “mousepad” is placed on the user's left-hand side of the electronic device 10 in a state where the user sits face to face with the electronic device 10 in the posture illustrated in FIG. 31, so the user can start performing an input operation to the keyboard (or an operation of the mousepad) with his/her right hand immediately after pressing the operation button 30L with his/her left hand. Namely, many people are right-handed, so, as described above, placing the operation button 30L on the left-hand side has an advantage in improving the operability.

Incidentally, if the two screens are used in a different manner that they are arranged side by side, i.e., in a state where the user holds the first main body portion 11 in his/her left hand and the second main body portion 12 in his/her right hand, the operation button 30L for displaying the “keyboard” is placed on the user's upper left; however, when the two screens are used by being arranged side by side as above (for example, as an electronic book), the keyboard is least likely to be used. Therefore, placing the operation button 30L at this position has an advantage with priority on the convenience to use the two screens by arranging them one above the other as illustrated in FIGS. 31 to 33.

A configuration of the system for displaying the above-mentioned “keyboard” or “mousepad” is explained with reference to FIG. 34.

Here, it is assumed that the displays 15 and 24 are both implemented as a touch-screen display.

The present system comprises a CPU 100, a main memory 101, a flash solid state drive, flash solid state disk (SSD) 102, a WiFi 103, a 3G 104, a built-in camera 105, a platform controller hub (PCH) 110, a display-signal converting module 111, a sound controller 112, a BIOS-ROM 113, an EC/KBC 118, the operation button 30R as “Home” button, the operation button 30L as “keyboard” button, a speaker 117, and the like.

The CPU 100 is a processor provided to control the operation of the electronic device 10, and executes an operating system (OS), various application programs, and the like which are loaded into the main memory 101 from a storage medium, such as the SSD 102. The application programs include an input control program. The input control program causes the CPU 100 to emulate the operation of the keyboard and a touch-pad with a touch-position detecting function of the touch-screen display (the touch panel). The CPU 100 also executes a system basic input output system (BIOS) stored in the BIOS-ROM 113. The system BIOS is a program for controlling hardware. The CPU 100 performs a process for drawing display data of “keyboard” and “mousepad”. The PCH 110 controls I/O devices, such as a Serial ATA, a USB, and a LAN.

The sound controller 112 is a sound controller for controlling the speaker 117.

The EC/KBC 118 has a function of turning the power of the electronic device 10 on or off depending on the user operation of the keyboard or the power-button switch.

A characteristic function performed by the control circuit 140 including the CPU 100 and the EC/KBC 118 in accordance with the OS or application program stored in the SSD 102 (a function of displaying a “keyboard” and a “mousepad”, etc.) is explained below with reference to FIGS. 35, 36, and 38.

As illustrated in FIG. 35, the CPU 100 operates in accordance with the OS or application program, thereby including an operation-mode identifying module 170 working as an operation-mode identifying means and a function switching module 180 working as a function switching means.

The operation-mode identifying module 170 identifies various modes of operation with respect to the operation buttons 30L and 30R working as function buttons.

The function switching module 180 controls switching among a plurality of functions defined by the OS or an application running on the OS depending on the mode of operation identified by the operation-mode identifying module 170.

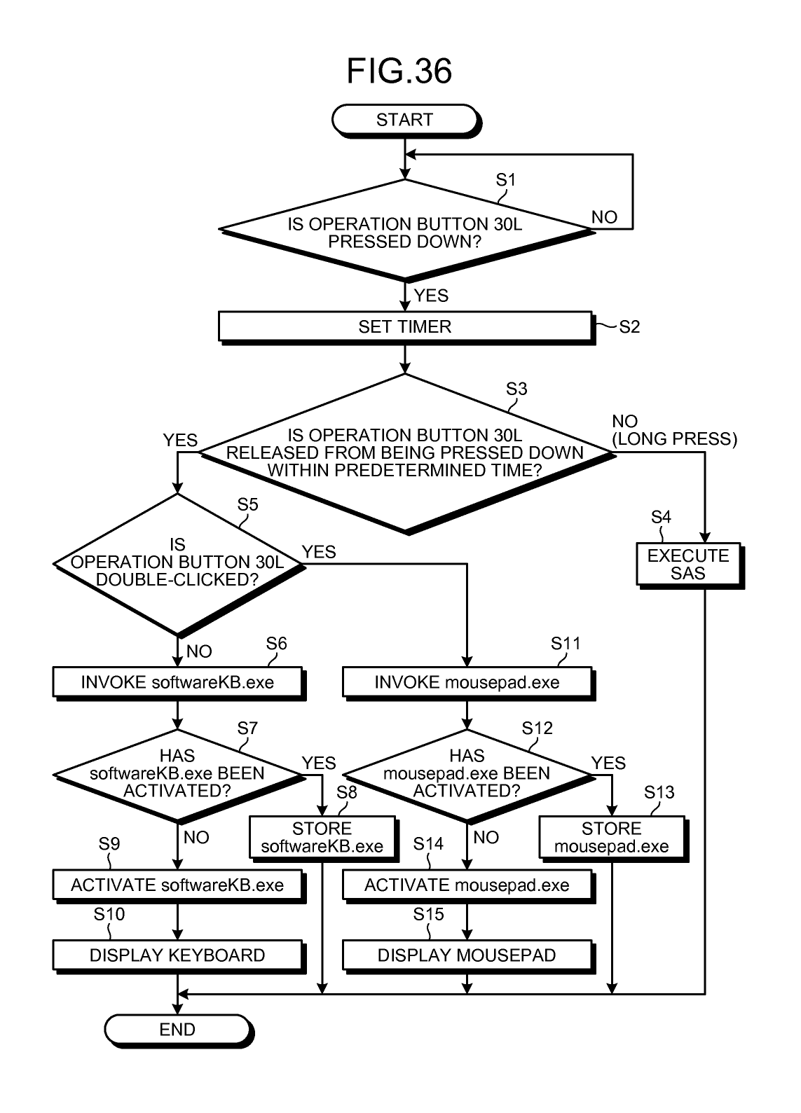

As illustrated in FIG. 36, when the operation button 30L is pressed down, for example, in a state where the dual-mode screen is displayed on the two displays 24 and 15 as illustrated in FIG. 31 (YES at S1), the EC/KBC 118 sets a timer (S2) and measures how long the operation button 30L will have been pressed down (for example, 4 seconds). Namely, at this time, whether the operation button 30L is pressed and held is determined.

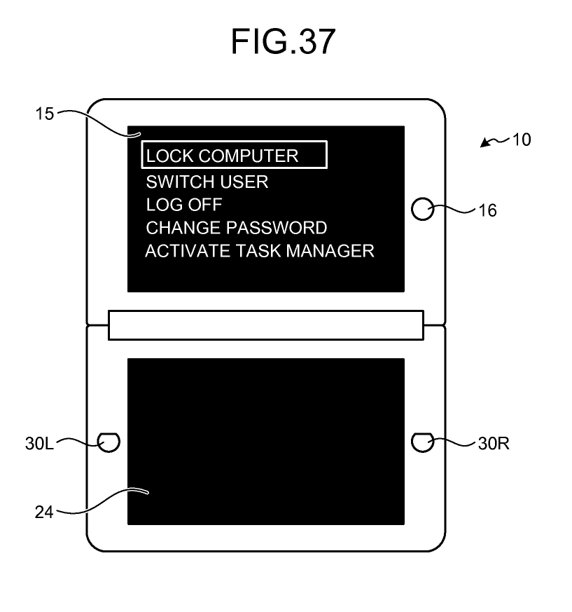

When the operation button 30L is pressed and held (NO at S3: the operation-mode identifying module 170), the EC/KBC 118 deems the “CTRL”, “ALT”, and “DEL” keys provided to a typical keyboard are pressed at the same time and generates a scan code of “CTRL”+“ALT”+“DEL”, and the CPU 100 executes a function called SAS (Secure Attention Sequence) for maintaining an application of the system or the like on the basis of the code generated by the EC/KBC 118 (S4: the function switching module 180). Consequently, for example, when an application makes no response, a user can open a menu (see FIG. 37) by pressing and holding the operation button 30L and force-quit the non-responding application. Incidentally, in the electronic device 10 according to the present embodiment, a time that the operation button 30L is deemed to be pressed and held is set to 4 seconds, so that execution of the SAS function can be made in the same sense as a force-quit of the power button 16 by pressing and holding the power button 16 (for 4 seconds or more).

On the other hand, when the operation button 30L is pressed for a short time just one time (YES at S3), the EC/KBC 118 again sets the timer and determines whether it is a double click (S5).

When the EC/KBC 118 determines that it is not a double click (NO at S5: the operation-mode identifying module 170), the CPU 100 invokes softwareKB.exe for displaying a keyboard (S6). At this time, if the same software has already been activated (YES at S7), the CPU 100 cancels the activation of softwareKB.exe invoked at S6 and stores softwareKB.exe (S8).

When it is determined that the same software has not been activated at S7 (NO at S7), the CPU 100 activates the software invoked at S6 (S9), and displays a keyboard as illustrated in FIG. 32 on the display 24 (S10: the function switching module 180).

On the other hand, when it is determined as a double click at S5 (YES at S5), the CPU 100 invokes mousepad.exe for displaying a mousepad (S11). At this time, if the same software has already been activated (YES at S12), the CPU 100 cancels the activation of mousepad.exe invoked at S11 and stores mousepad.exe (S13).

When it is determined that the same software has not been activated at S12 (NO at S12), the CPU 100 activates the software invoked at S11 (S14), and displays a mousepad as illustrated in FIG. 33 on the display 24 (S15: the function switching module 180).

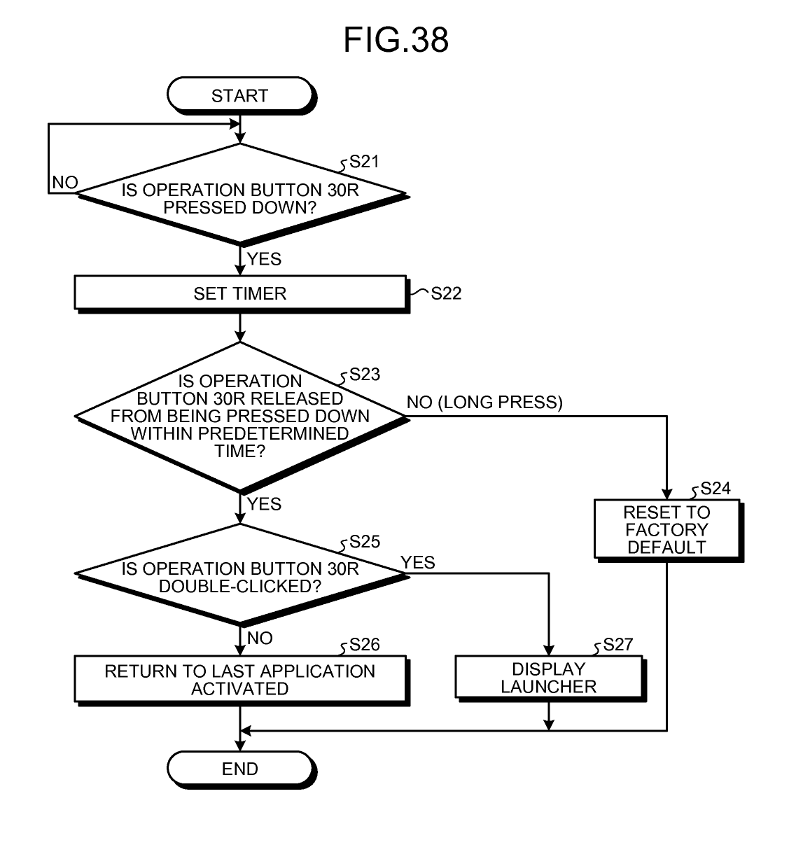

The operation, such as how the control circuit 140 displays “launcher”, is explained with reference to FIG. 38.

As illustrated in FIG. 38, when the operation button 30R is pressed down, for example, in a state where the dual-mode screen is displayed on the two displays 24 and 15 as illustrated in FIG. 31 (YES at S21), the EC/KBC 118 sets a timer (S22) and measures how long the operation button 30R is pressed down (for example, 4 seconds). Namely, at this time, whether the operation button 30R is pressed and held is determined.

When the operation button 30R is pressed and held (NO at S23: the operation-mode identifying module 170), the CPU 100 resets the display setting to the factory default, “prerecorded display setting” (S24: the function switching module 180). Consequently, for example, when a user has changed the display setting many times and cannot reset to the factory default, the user just presses and holds the operation button 30R, so that the display setting can be reset to the factory default.

On the other hand, when the operation button 30R is pressed for a short time just one time (YES at S23), the EC/KBC 118 again sets the timer and determines whether it is a double click (S25).

When the EC/KBC 118 determines that it is not a double click (NO at S25), the CPU 100 returns to the last application activated by the electronic device 10 (S26).

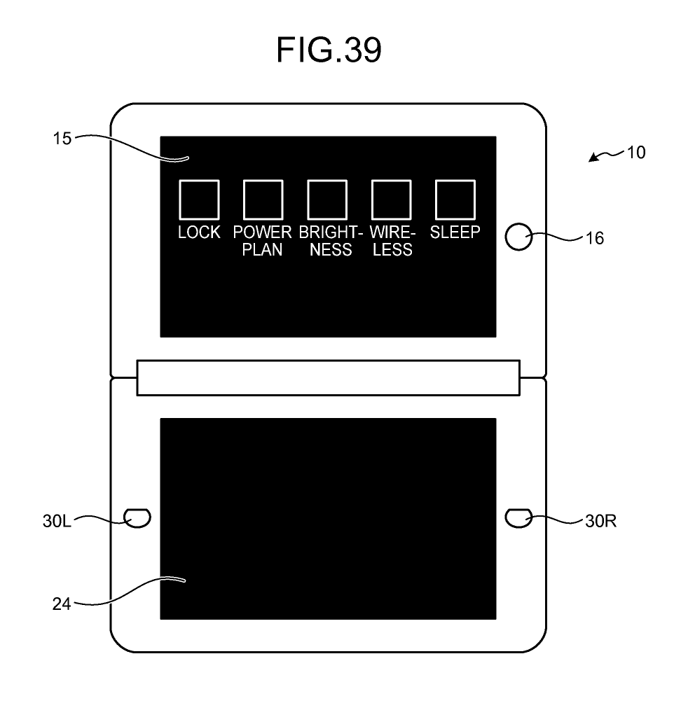

On the other hand, when it is determined as a double click at S25 (YES at S25: the operation-mode identifying module 170), the CPU 100 displays a launcher (see FIG. 39) displaying a list of the previously-registered files and programs which are represented by icons (S27: the function switching module 180). As illustrated in FIG. 39, functions of the icons displayed in the launcher include a system lock function, a power plan select function, a display brightness adjust function, a wireless ON/OFF function, a sleep function, and the like.

In this manner, in the electronic device 10 according to the present embodiment, the operation button 30L, the operation button 30R, and the power button 16 each can fulfill a different function from the original function by being pressed and held (for 4 seconds or more).

In this manner, in the electronic device 10 according to the present embodiment, one button is used for a plurality of functions including the SAS function, so it is possible to achieve reduction in the number of parts, improvement of convenience for users, and improvement of design of the device.

Incidentally, in the electronic device 10 according to the present embodiment, it is configured that the SAS function is performed when the operation button 30L is pressed and held; however, whether to execute the SAS function is not limited to depending on whether the operation button 30L is pressed long or short. Alternatively, the SAS function can be performed depending on either a single click or a double click or depending on a code pattern composed of a combination of short and long codes, such as a Morse code.

As illustrated in FIG. 40, the electronic device 10 according to the present embodiment comprises the swing supporting mechanism 27 having the same configuration as the swing supporting mechanism 7 in the first embodiment. Namely, the swing supporting mechanism 27 has the support bracket portion 22c provided to the enclosure 22, the elastic bushing 28 attached to the support bracket portion 22c, the connecting portion 27a penetrating through a through-hole 28a formed as a penetration portion on the elastic bushing 28, and a screw 29 as a uniting body attached to the connecting portion 27a. In the present embodiment, the support bracket portion 22c corresponds to a base portion. Furthermore, the frame 23c corresponds to a frame member, and the front wall portion 23p of the frame 23c corresponds to a supported portion.

The support bracket portion 22c is provided to the periphery of the bottom wall portion 22a of the enclosure 22 as a boss portion cylindrically projecting forward, i.e., toward the side of the front wall portion 23p provided as a supported portion. A circular through-hole 22e is formed on the center of a top wall portion 22d of the support bracket portion 22c, and an inward flange portion 22f is formed around the through-hole 22e.

The elastic bushing 28 is formed of an elastic material, such as elastomer (for example, synthetic rubber), into a cylindrical shape. On the center of an outer circumferential surface 28b of the elastic bushing 28 in an axial direction (the up-down direction in FIG. 40), an outer circumferential groove 28c is formed over the whole circumference in a circumferential direction. By fitting the outer circumferential groove 28c with the flange portion 22f of the support bracket portion 22c, the elastic bushing 28 is attached to the support bracket portion 22c.

As the elastic bushing 28 deforms elastically, a worker inserts the elastic bushing 28 into the through-hole 22e from the front side, so that the elastic bushing 28 can be relatively easily attached to the support bracket portion 22c. The elastic bushing 28 has an asymmetric shape, i.e., the elastic bushing 28 is asymmetrical on the both sides in the axial direction. This prevents the worker from attaching the elastic bushing 28 in a wrong posture to the support bracket portion 22c. Incidentally, as illustrated in FIG. 40, also in the present embodiment, inclined surfaces 28d and 28e are formed on the elastic bushing 28 in the same manner as the elastic bushing 8 according to the first embodiment. Furthermore, in the same manner as the elastic bushing 8 according to the first embodiment, the elastic bushing 28 has a front-side protrudent portion 28f held between the frame 23c and the flange portion 22f and a back-side protrudent portion 28g held between a head portion 29a of the screw 29 and the flange portion 22f.

The connecting portion 27a is formed as a boss portion cylindrically projecting backward from the frame 23c. As illustrated in FIG. 40, in an assembled state, the connecting portion 27a penetrates through the through-hole 22e of the support bracket portion 22c, and projects to the side of the back surface (the rear surface) of the support bracket portion 22c. On the connecting portion 27a, a female screw hole 27b opening backward is formed as a female screw portion.

The screw 29 has the head portion 29a and a male screw portion 29b screwed into the female screw hole 27b. The screw 29 is screwed until the head portion 29a butts an end surface 27c of the connecting portion 27a.

A worker attaches the elastic bushing 28 to the support bracket portion 22c from the front side, and brings the touch panel unit 23 close to the enclosure 22 from the front and inserts the connecting portion 27a into the through-hole 28a of the elastic bushing 28, and then tightens up the screw 29 into the female screw hole 27b of the connecting portion 27a provide as a boss portion from the back side, thereby the swing supporting mechanism 27 illustrated in FIG. 40 is composed. Namely, it is configured that the elastic bushing 28 is fitted into the support bracket portion 22c, so the worker can perform the assembly work more easily and smoothly as compared with the case of adhering or screwing an elastic body.

In the same manner as in the first embodiment, also in the present embodiment, the connecting portion 27a penetrates through the through-hole 28a of the elastic bushing 28 in the front-back direction of the display 24. Moreover, also in the present embodiment, in a state where the swing supporting mechanism 27 has been assembled, the front-side protrudent portion 28f of the elastic bushing 28 lies between the support bracket portion 22c as a part of the enclosure 22 and the frame 23c of the touch panel unit 23 placed on the front side of the support bracket portion 22c, and the back-side protrudent portion 28g of the elastic bushing 28 lies between the support bracket portion 22c and the screw 29 placed on the back side of the support bracket portion 22c. Furthermore, the elastic bushing 28 is placed so as to surround the connecting portion 27a. Moreover, also in the present embodiment, the support bracket portion 22c is formed as a boss portion projecting forward (i.e., toward the side of the front wall portion 23p of the frame 23c) from the bottom wall portion 22a of the enclosure 22.

Also in the present embodiment, as a structure for reducing the area of contact between the elastic bushing 28 and the touch panel unit 23 in the assembled state, a circular projection portion 28h is provided on an inner surface of the through-hole 28a of the elastic bushing 28, and also a plurality of projection portions 23g are circumferentially placed on a portion of the back surface 23f of the frame 23c opposed to the elastic bushing 28. Incidentally, these are only examples; alternatively, for example, a projection portion can be provided to the connecting portion 27a or the front surface of the elastic bushing 28, and the projection portion can be formed into a circular shape or a plurality of projection portions can be circumferentially placed.

As illustrated in FIG. 22, in the present embodiment, the screw 29 composing the swing supporting mechanism 27, the screw 34 composing the push button mechanism 30, and the projection portions 23r are exposed on the side of the back surface 22g of the bottom wall portion 22a. Namely, in a state before the screws 29 and 34 are tightened, on the side of the back surface 22g of the bottom wall portion 22a, the end surface 27c of the connecting portion 27a composing the swing supporting mechanism 27 (see FIG. 40) is exposed, and the boss portion 23q and the projection portions 23r are also exposed through a through-hole 22j formed on the bottom wall portion 22a. Therefore, by tightening the screws 29 and 34 in a state where the battery pack 17 is not fitted into the concave portion 21d, the swing supporting mechanism 27 and the push button mechanism 30 can be composed more easily and smoothly and eventually the touch panel unit 23 can be attached to the enclosure 22. Furthermore, the tightening of the screws 29 and 34 can be performed at a time, so it is possible to further increase the efficiency of assembly work. Then, the screws 29 and 34 are covered with the battery pack 17, so it is possible to prevent the touch panel unit 23 and the push button mechanism 30 from coming off from the enclosure 22 by avoiding, for example, a case where a user mistakenly unscrews the screws 29 and 34. Moreover, the configuration can be simplified as compared with the case where separate cover bodies for covering the screws 29 and 34 are provided. Furthermore, as illustrated in FIG. 40, as an example of a cover, a seal 22i can be attached to the back surface 22g so as to cover the screws 29 and 34. Moreover, in the present embodiment, the battery pack 17 is used as a lid of the concave portion 21d, so the enclosure 22 can be made thinner. Incidentally, the projection portions 23r for positioning the circuit board 31 are exposed through the through-hole 22j, so a worker can look the mounting state of the circuit board 31.

In this manner, the electronic device 10 according to the present embodiment differs in specification, such as the size, the number of parts, and the layout, from the AIO 1 according to the first embodiment, but has the swing supporting mechanism 27 having the same configuration as the swing supporting mechanism 7 in the first embodiment. Namely, the electronic device 10 having the swing supporting mechanism 27 according to the present embodiment can achieve the same effect as the AIO 1 having the swing supporting mechanism 7 according to the first embodiment. The function as a restraining module of the elastic bushing 28 of the swing supporting mechanism 27 is the same as the function as a restraining module of the elastic bushing 8 of the swing supporting mechanism 7 according to the first embodiment.

As described above, the electronic device 10 according to the present embodiment comprises the push button mechanism 30 identical to that is in the first embodiment as an operation mechanism. Therefore, the same effect as in the first embodiment can be achieved.

Especially, in the present embodiment, a keyboard can be displayed on the display 24 on the side of the first main body portion 11 only by clicking the operation button 30L placed on the left side of the first main body portion 11 in a state where the dual-mode screen which the two screens are arranged one above the other as illustrated in FIG. 31 is displayed. Consequently, the electronic device 10 can be instantly switched, for example, from the state illustrated in FIG. 31, i.e., a state in which the dual-mode screen is displayed to a state in which keyboard input can be made (the state illustrated in FIG. 32), so it is possible to improve the convenience.

The electronic device 10 according to the present embodiment can be used, for example, in a manner that the electronic device 10 is rotated by 90 degrees in a clockwise direction from a state where the first and second main body portions 11 and 12 are in the open state as illustrated in FIG. 18 (i.e., in a manner that the two screens are arranged side by side). In this case, a user holds, for example, the horizontal frame portion 23h of the first main body portion 11 in his/her left hand and the horizontal frame portion of the second main body portion 12 in his/her right hand.

In this state, the operation button 30R for Home provided on the first main body portion 11 is located below the user's left hand, and the power button 16 provided on the second main body portion 12 is located below the user's right hand. Namely, in this example of use of the electronic device 10 in which the two screens are arranged side by side, a user can easily operate the operation button 30R with his/her left hand, and can easily operate the power button 16 with his/her right hand. Incidentally, in this state, the operation button 30L for displaying a keyboard is located above the user's left hand; however, when the electronic device 10 is used as an electronic book, the keyboard is less likely to be used, so there is no harm in placing the operation button 30L for displaying a keyboard on the upper side of the first main body portion 11.

In the present embodiment, a plurality of (two, in the present embodiment) boss portions 23q are placed on the both sides of the vertical frame portions 23i, which is a belt-like portion, in the extending direction (i.e., the Y direction) across the cover body 33. Furthermore, in the present embodiment, the boss portions 23q are placed on the side of one end of the vertical frame portion 23i in the width direction, and the projection portions 23r are placed on the side of the other end of the vertical frame portion 23i in the width direction. Consequently, the boss portions 23q and the projection portions 23r are efficiently placed on the vertical frame portion 23i, so it is possible to prevent the size of the vertical frame portion 23i, which is a belt-like portion, and eventually the touch panel unit 23 from increasing. Furthermore, in the present embodiment, the boss portions 23q are placed at the position closer to the touch panel 23a than the projection portions 23r. Therefore, the circuit board 31 can be supported more stably. Moreover, in the present embodiment, the magnet 36 is provided on the back surface 23f of the front wall portion 23p, and the circuit board 31 covers the back side of the magnet 36. Therefore, the circuit board 31 can be used as a cover of the magnet 36.

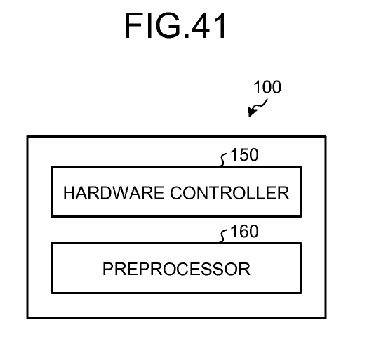

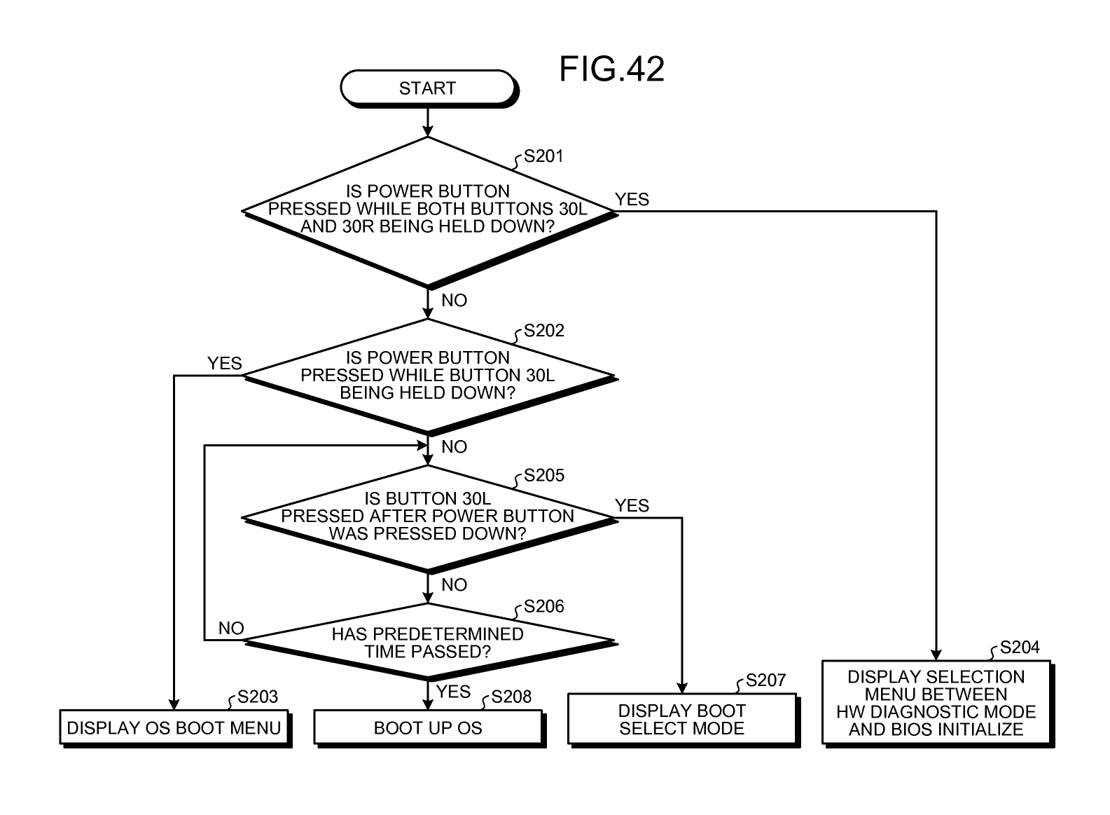

A characteristic function performed by the control circuit 140 including the CPU 100 and the EC/KBC 118 in accordance with the system BIOS stored in the BIOS-ROM 113 is explained with reference to FIGS. 41 and 42.

As illustrated in FIG. 41, the CPU 100 operates in accordance with the system BIOS, thereby including a hardware control module 150 working as a hardware control means and an OS-boot preprocessing module 160 working as an OS-boot preprocessing means.

The hardware control module 150 is activated in accordance with the power-on operation with respect to the power button 16, and provides basic I/O means with respect to various hardware including the operation button 30L and the operation button 30R to the OS.

The OS-boot preprocessing module 160 executes a process to be performed before the OS is booted up if a predetermined operation is made on at least any one of the operation button 30L and the operation button 30R within a predetermined time after the power-on operation with respect to the power button 16.

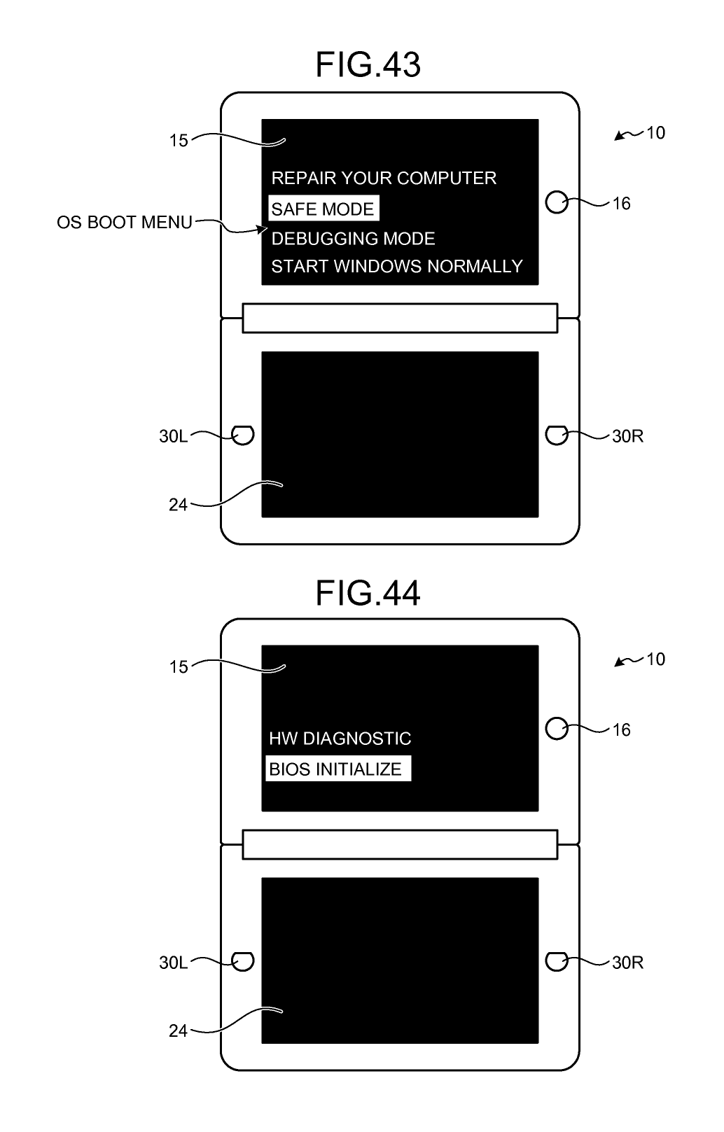

As illustrated in FIG. 42, when the EC/KBC 118 determines that the power button 16 is pressed with the operation button 30L held down (NO at S201, YES at S202), the CPU 100 displays an “OS boot menu” for setting the operation at the time of boot-up as illustrated in FIG. 43 on the display 15, and displays nothing on the display 24 (S203).

In a state where the “OS boot menu” as illustrated in FIG. 43 is displayed, the operation button 30L works as a selection button. Namely, an operator presses the operation button 30L until a boot mode selected is highlighted in reverse video. On the other hand, in the state where the “OS boot menu” as illustrated in FIG. 43 is displayed, the operation button 30R works as an OK button. Namely, after confirming that the boot mode selected is highlighted in reverse video, the operator presses the operation button 30R to determine the selection.

In this manner, an operator just presses the operation button 30L and the power button 16 in a predetermined way, so that the electronic device 10 according to the second embodiment can boot up the “OS boot menu” as illustrated in FIG. 43 and perform processing.

On the other hand, as illustrated in FIG. 42, when the EC/KBC 118 determines that the power button 16 is pressed with both the operation button 30L and the operation button 30R held down (YES at S201), the CPU 100 displays a “HW diagnostic mode/BIOS initialize menu” as illustrated in FIG. 44 on the display 15, and displays nothing on the display 24 (S204). In the “HW diagnostic mode/BIOS initialize menu”, a selection menu for selecting any of “HW Diagnostic” and “BIOS Initialize” is displayed. The HW diagnostic mode is a mode to diagnose a status of hardware.

In a state where the “HW diagnostic mode/BIOS initialize menu” as illustrated in FIG. 44 is displayed, the operation button 30L works as a selection button. Namely, an operator presses the operation button 30L until a menu selected is highlighted in reverse video. On the other hand, in the state where the “HW diagnostic mode/BIOS initialize menu” as illustrated in FIG. 44 is displayed, the operation button 30R works as an OK button. Namely, after confirming that the menu selected is highlighted in reverse video, the operator presses the operation button 30R to determine the selection.

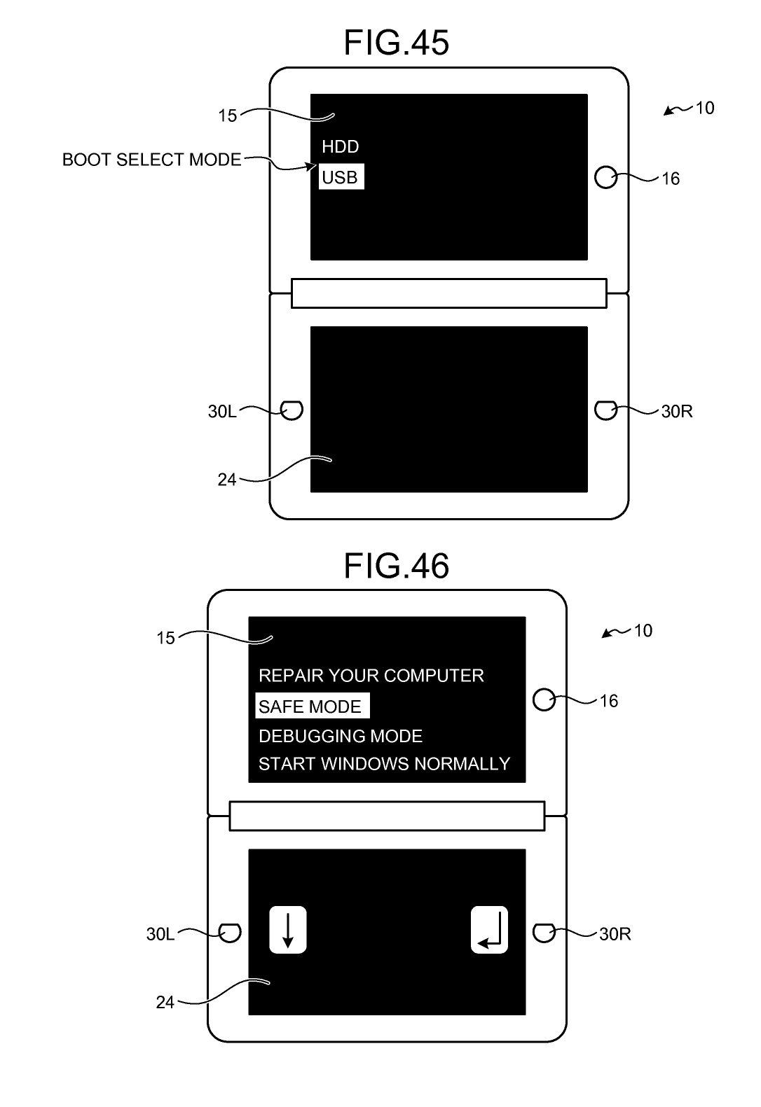

As illustrated in FIG. 42, when the EC/KBC 118 determines that the operation button 30L is pressed within a predetermined time (for example, within 2 seconds) since the power button 16 was pressed down (NO at S201, NO at S202, YES at S205), the CPU 100 displays a “boot select mode” for setting the selection of a boot disk as illustrated in FIG. 45 on the display 15, and displays nothing on the display 24 (S207). In the “boot select mode”, a selection menu for selecting any of “internal hard drive (HDD)” and “external hard drive (USB)” is displayed.

In a state where the “boot select mode” as illustrated in FIG. 45 is displayed, the operation button 30L works as a selection button. Namely, an operator presses the operation button 30L until a hard drive selected is highlighted in reverse video. On the other hand, in the state where the “boot select mode” as illustrated in FIG. 45 is displayed, the operation button 30R works as an OK button. Namely, after confirming that the hard drive selected is highlighted in reverse video, the operator presses the operation button 30R to determine the selection.

Incidentally, as illustrated in FIG. 42, when the EC/KBC 118 determines that the operation button 30L is not pressed within a predetermined time (for example, within 2 seconds) since the power button 16 was pressed (NO at S201, NO at S202, NO at S205, YES at S206), the CPU 100 boots up the OS (S208).

After the boot-up of the OS, the operation button 30L is assigned to work as a button for displaying a keyboard illustrated in FIG. 32, and the operation button 30R is assigned to work as a button for returning to the last application activated by the electronic device 10. Namely, after the boot-up of the OS, the operation button 30L and the operation button 30R do not take over the control of the operation specification before the OS is booted up (the operation button 30L=Down Arrow Key (↓), the operation button 30R=Enter Key), and work as a user-arbitrarily-settable “programmable button” as a function selection on the OS.

In this manner, the electronic device 10 according to the second embodiment achieves the following functions depending on how to press the operation button 30L, the operation button 30R, and the power button 16:

(1) Activation of the “OS boot menu”, the “HW diagnostic mode/BIOS initialize menu”, and the “boot select mode” before the OS is booted up is controlled.

(2) Before the OS is booted up, the operation button 30L works as a select function (Down Arrow Key (↓) and the operation button 30R works as a determine function (Enter Key).

(3) After the OS is booted up, the operation button 30L and the operation button 30R work as a programmable button to control a valid function on the OS.

In this manner, the electronic device 10 according to the second embodiment, which is not equipped with a hardware keyboard, comprises at least one function button (the operation buttons 30L and 30R) for controlling a function defined on the OS, and can control a function within a BIOS control range of the main body of the electronic device 10, a specific activation operation before the OS is booted up, selection of a function which can be arbitrarily set after the OS is booted up, and the like depending on how to press the operation buttons 30L and 30R in combination with the power button 16, a combination of the buttons, and the like.

Incidentally, in FIGS. 43 to 45, nothing is displayed on the display 24; alternatively, as illustrated in FIG. 46, an icon of Down Arrow Key (↓) indicating the function of the operation button 30L and an icon of Enter Key indicating the function of the operation button 30R can be displayed on the display 24 with the icons placed near the corresponding buttons. This enables a user to clearly understand the functions of the operation buttons 30L and 30R.

Incidentally, the system BIOS or application program executed by the electronic device 10 according to the second embodiment can be provided by being recorded on a computer-readable recording medium, such as a CD-ROM, a flexible disk (FD), a CD-R, or a DVD, in an installable or executable file format.

The system BIOS or application program executed by the electronic device 10 according to the second embodiment can be stored on a computer connected to a network, such as the Internet, so as to provide the system BIOS or application program by being downloaded via the network. Moreover, the system BIOS or application program executed by the electronic device 10 according to the second embodiment can be provided or distributed via a network, such as the Internet.

### Modification

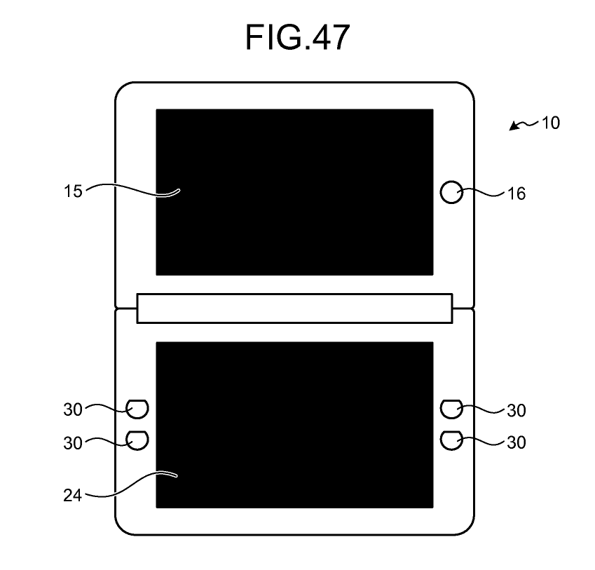

As a modification of the electronic device 10 according to the second embodiment, as illustrated in FIG. 47, the number of operation buttons 30 can be increased, and the number of types of button control before the OS is booted up can be increased or the control range can be expanded by the operation that the power button 16 is pressed with two of the operation buttons 30 held down at the same time, the operation to define the order of the operation buttons 30 to be pressed, assignment of Keys, and the like. For example, the complicated operations or setting processes, such as “display of a BIOS setting screen”, security processing of a “boot password”, etc., can be achieved.

While the above embodiments are described as being applied to a television set and a notebook personal computer having two display screens, the embodiments can be applied to other electronic devices having a display and a front panel on the front side of the display, such as a computer (a notebook computer, a desktop computer) having one display screen, a personal digital assistant (PDA), a smartbook, a smartphone, and a mobile phone unit.

Moreover, the various modules of the systems described herein can be implemented as software applications, hardware and/or software modules, or components on one or more computers, such as servers. While the various modules are illustrated separately, they may share some or all of the same underlying logic or code.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic device comprising:
a display module configured to display image data related to an application module or image data based on received broadcast waves;
at least one function button separate from a hardware keyboard comprising a plurality of keys;
an operation-mode identifying module configured to identify a mode of operation with respect to the function button; and
a function switching module configured to switch between a plurality of functions or the application module, with regards to the identified mode of operation.

2. The electronic device of claim 1, wherein the electronic device is configured to execute a secure attention sequence for maintenance of an application of a system, when the function button is pressed and held for a threshold time or longer.

3. The electronic device of claim 1, wherein the electronic device is configured to reset to factory default setting, when the function button is pressed and held for a threshold time or longer.

4. The electronic device of claim 2, wherein the threshold time is substantially equal to a long-press time for which a power button is pressed and held in order to force-quit the electronic device.

5. The electronic device of claim 3, wherein the threshold time is substantially equal to a long-press time for which a power button is pressed and held in order to force-quit the electronic device.

6. The electronic device of claim 1, wherein the electronic device is configured to display a launcher displaying a set of icons representing a list of programs and files registered in advance, on the display module when the function button is double-clicked.

7. An electronic device comprising:
a display module configured to display a keyboard, comprising a plurality of keys, to be used an application module;
at least one function button separate from a hardware keyboard comprising a plurality of keys;
an operation-mode identifying module configured to identify a mode of operation with respect to the function button; and
a function switching module configured to switch between a plurality of functions or the application module, with regards to the identified mode of operation.

8. The electronic device of claim 7, wherein the electronic device is configured to execute a secure attention sequence for maintenance of an application of a system, when the function button is pressed and held for a threshold time or longer.

9. The electronic device of claim 7, wherein the electronic device is configured to reset to factory default setting, when the function button is pressed and held for a threshold time or longer.

10. The electronic device of claim 8, wherein the threshold time is substantially equal to a long-press time for which a power button is pressed and held in order to force-quit the electronic device.

11. The electronic device of claim 9, wherein the threshold time is substantially equal to a long-press time for which a power button is pressed and held in order to force-quit the electronic device.

12. The electronic device of claim 7, wherein the electronic device is configured to display a launcher displaying a set of icons representing a list of programs and files registered in advance, on the display module when the function button is double-clicked.

13. A computer program product having a computer readable non-transitory medium comprising programmed instructions embodied in the medium that, when executed, cause a computer to:
identify a mode of operation with respect to at least one function button, separate from a hardware keyboard comprising a plurality of keys; and
control switching a plurality of functions or an application module with regards to the identified mode of operation.
